(19) United States
(12) Patent Application Publication
(10) Pub. No.: US 2026/0223379 A1
(43) Pub. Date: Jul. 30, 2026

(54) CAPACITOR INCLUDING A TETRAGONAL HAFNIUM ZIRCONIUM OXIDE NODE DIELECTRIC AND METHODS OF FORMING THE SAME

(71) Applicant: Taiwan Semiconductor Manufacturing Company Limited, Hsinchu (TW)

(72) Inventors: Cheng-Te Lee, Chupei City (TW); Min-Ying Tsai, Kaohsiung City (TW); Chieh-Jung Li, New Taipei City (TW)

(21) Appl. No.: 19/037,318

(22) Filed: Jan. 27, 2025

(51) Int. Cl. H10D 1/68; H01L 23/522; H01L 23/528; H10D 1/00

(52) U.S. Cl. CPC H10D 1/68; H10D 1/042; H10D 1/716; H10W 20/42; H10W 20/435; H10W 20/496

(57) ABSTRACT

A device structure may be formed by depositing a first metallic electrode layer over a substrate; depositing a node dielectric layer comprising an amorphous hafnium zirconium oxide layer having a material composition of Hf_{(1-α)}Zr_{α}O₂ over the first metallic electrode layer, wherein a value of α is in a range from 0.50 to 0.90; depositing a second metallic electrode layer over the node dielectric layer; and annealing the amorphous hafnium zirconium oxide layer into a crystalline hafnium zirconium oxide layer. A sum of a fraction of hafnium zirconium oxide in a tetragonal phase and a fraction of hafnium zirconium oxide in an orthorhombic phase for the crystalline hafnium zirconium oxide layer may be greater than 0.40. A combination of the first metallic electrode layer, the node dielectric layer, and the second metallic electrode layer comprises a capacitor structure, which may provide high capacitance and enhanced reliability.

### BACKGROUND

Capacitors are used in semiconductor chips for many applications such as power supply stabilization. Capacitors that may provide high capacitance with a small device footprint are desirable.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating the distribution in the fractions of various phases in a fully crystallized hafnium zirconium material used in embodiments of the present disclosure.

FIGS. 2A-2J are various configurations for a node dielectric layer in any capacitor structure in embodiments of the present disclosure.

FIG. 3A is a top down view of a first embodiment structure after formation of deep trenches in a first substrate according to an embodiment of the present disclosure. An inset illustrates a magnified view of a region of the first configuration of the embodiment structure.

FIG. 3B is a vertical cross-sectional view of a region of the first embodiment structure along the vertical plane B-B′ of FIG. 3A.

FIG. 4 is a vertical cross-sectional view of a region of the first embodiment structure after formation of a layer stack including at least three metallic electrode layers interlaced with at least two node dielectric layers according to an embodiment of the present disclosure.

FIG. 5 is a vertical cross-sectional view of a peripheral region of the first embodiment structure after patterning the layer stack according to an embodiment of the present disclosure.

FIG. 6 is a vertical cross-sectional view of a region of the first embodiment structure after formation of a planarization dielectric layer and contact via structures according to an embodiment of the present disclosure.

FIG. 7 is a vertical cross-sectional view of an exemplary chip assembly incorporating a semiconductor die containing a deep trench capacitor according to an embodiment of the present disclosure.

FIGS. 8A-8C are sequential vertical cross-sectional views of a second embodiment structure including a capacitor structure during a sequence of manufacturing steps according to an embodiment of the present disclosure.

FIGS. 9A-9C are sequential vertical cross-sectional views of a third embodiment structure including a capacitor structure during a sequence of manufacturing steps according to an embodiment of the present disclosure.

FIGS. 10A-10C are sequential vertical cross-sectional views of a fourth embodiment structure including a capacitor structure during a sequence of manufacturing steps according to an embodiment of the present disclosure.

FIGS. 11A-11C are sequential vertical cross-sectional views of a fifth embodiment structure including a capacitor structure during a sequence of manufacturing steps according to an embodiment of the present disclosure.

FIG. 12 is a first flowchart that illustrates the general processing steps of the methods of the present disclosure.

FIG. 13 is a second flowchart that illustrates the general processing steps of the methods of the present disclosure.

### DETAILED DESCRIPTION

The following disclosure provides many different embodiments, or examples, for implementing various features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The present disclosure is directed to semiconductor devices, and specifically to capacitor structures and methods of forming the same. Various embodiment capacitor structures of the present disclosure use a crystalline hafnium zirconium oxide layer including portions having a tetragonal phase. Generally, the fraction of the tetragonal phase within the crystalline hafnium zirconium oxide layer is not 100%, and additional phases such as an orthorhombic phase and/or a monoclinic phase may be present within the crystalline hafnium zirconium oxide layer. Embodiments of the present disclosure provide methods and structures for suppressing adverse effects of the presence of undesirable phases of the crystalline hafnium zirconium oxide, for example, by increasing the fraction of the tetragonal phase, by using at least one high band gap dielectric layer providing leakage suppression and/or increase in the depolarization field for a ferroelectric material in an orthorhombic phase, and/or by using multiple layers of crystalline hafnium zirconium oxide for the purpose of reducing a thickness of each crystalline hafnium zirconium oxide layer and increasing the fraction of the tetragonal phase. In addition, various embodiments for capacitor structures are disclosed, which may be used to leverage the high effective dielectric constant of the node dielectric layer of the present disclosure to provide high capacitance per area. Such capacitor structures may comprise deep trench capacitors, planar capacitors, or contoured capacitors. The various aspects of the present disclosure are now described with reference to accompanying drawings.

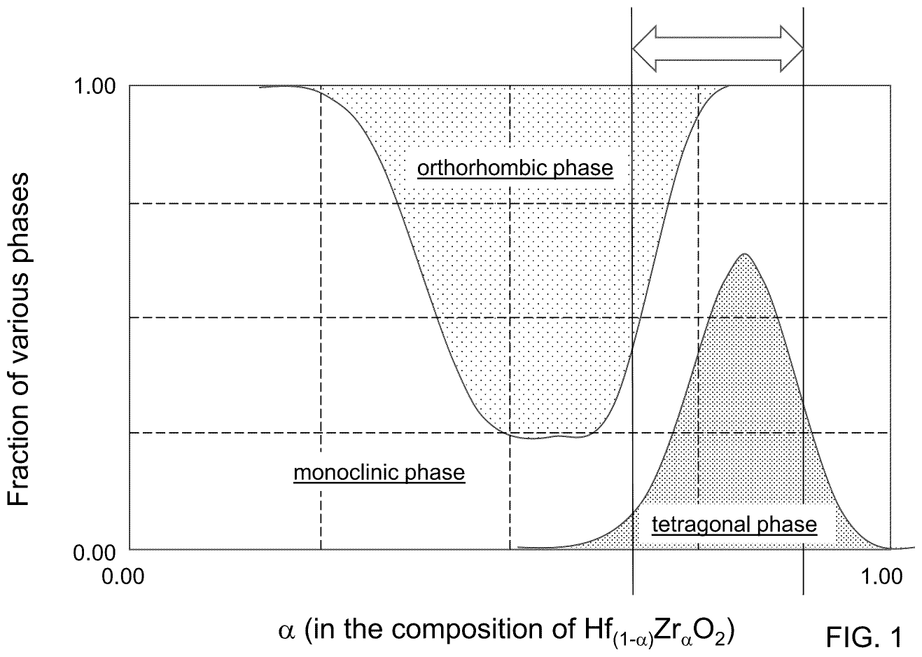

Referring to FIG. 1, a diagram illustrates the distribution in the fractions of various phases in a fully crystallized hafnium zirconium material used in embodiments of the present disclosure. As used herein, each fraction of a phase of a material within a material portion may be calculated by dividing the number of atoms arranged in the phase of the material by the total number of atoms within the material. Thus, each fraction for a selected phase is a dimensionless non-negative number not greater than 1.0. Generally, hafnium zirconium oxide may have a composition of Hf_{(1-α)}Zr_{α}O₂, in which the value of α is greater than 0.0 and is less than 1.0. For the purpose of use as a node dielectric material, hafnium zirconium oxide may be deposited as a thin film of an amorphous material. The thickness of such a hafnium zirconium oxide film may be in a range from 5 nm to 50 nm, although lesser or greater thicknesses may also be used. Amorphous hafnium zirconium oxide has a lower dielectric constant than various phases of a crystalline hafnium silicon oxide. Thus, it is advantageous to anneal an amorphous hafnium zirconium oxide film into a crystalline hafnium zirconium oxide layer for the purpose of use as a node dielectric material for a capacitor structure.

Generally, large crystalline domains and a greater fraction of a preferable crystallographic phases (such as a tetragonal phase) may be obtained by depositing an amorphous hafnium zirconium oxide layer and by annealing the amorphous hafnium zirconium oxide layer instead of attempting to deposit a crystalline hafnium zirconium oxide layer. Further, during the direct deposition of a crystalline hafnium zirconium oxide layer a high deposition temperature is desired, such as a deposition temperature greater than at least 500 degrees, which is impractical for formation of back-end-of-line (BEOL) capacitor structures (i.e., capacitor structures that are formed in the metal interconnect levels). In embodiments in which an anneal process that induces complete crystallization of an zirconium oxide layer is used, the distribution of crystallographic phases in the crystallized hafnium zirconium oxide layer depends primarily on the material composition of the amorphous hafnium zirconium oxide layer as deposited, and secondarily on the anneal conditions and the surface characteristics of the surface on which the amorphous hafnium zirconium oxide layer is deposited. Ignoring the secondary effects caused by the process parameters of the anneal process and the surface characteristics, FIG. 1 illustrates the general trend in the fractions of various crystallographic phases in a completely crystallized hafnium zirconium oxide layer, i.e., a hafnium zirconium oxide layer that is obtained by annealing an amorphous hafnium zirconium oxide layer under an anneal condition that crystallizes 100% of the material without leaving any material portion amorphous.

The hafnium zirconium oxide layer for use within a node dielectric layer of the present disclosure may be deposited by atomic layer deposition (ALD), chemical vapor deposition (CVD), or physical vapor deposition (PVD) as an amorphous material or as a predominantly amorphous material. An anneal process may be performed to convert the amorphous Hf_{(1-α)}Zr_{α}O₂ material into a polycrystalline material. In embodiments in which the node dielectric layer 15 is formed as a front-end-of-line (FEOL) structure, i.e., prior to formation of metal interconnect structures, a rapid thermal anneal (RTA) process may be performed to anneal the amorphous Hf_{(1-α)}Zr_{α}O₂ material into a crystalline Hf_{(1-α)}Zr_{α}O₂ material. The elevated temperature during the RTA process may be in a range from 600° C. to 900° C., and the duration of the elevated temperature may be in a range from 1 second to 180 seconds. A furnace anneal with an anneal temperature in a range from 400° C. to 600° C. tends to increase the fraction of the orthorhombic phase and/or the fraction of the monoclinic phase. Thus, an RTA process is preferred over a furnace anneal process. Alternatively, a laser anneal process may be used in lieu of an RTA anneal. The fraction of remnant amorphous Hf_{(1-α)}Zr_{α}O₂ material in an annealed Hf_{(1-α)}Zr_{α}O₂ layer decreases rapidly with an increase in the anneal temperature, and amorphous Hf_{(1-α)}Zr_{α}O₂ material portions may be eliminated upon selection of suitable anneal conditions.

Generally, Hf_{(1-α)}Zr_{α}O₂, (0<α<1) is a dielectric material that provides a dielectric constant greater than 15. The dielectric constant (k) of Hf_{(1-α)}Zr_{α}O₂, (0<α<1) depends on the crystalline phase of the material. For example, Hf_{(1-α)}Zr_{α}O₂, (0<α<1) in a tetragonal phase provides a dielectric constant in a range from 35 to 50, which is the highest dielectric constant range among the various phases of the Hf_{(1-α)}Zr_{α}O₂, (0<α<1).

Hf_{(1-α)}Zr_{α}O₂, (0<α<1) in an orthorhombic phase has a dielectric constant in a range from 20 to 30, and may exhibit ferroelectric behavior. The ferroelectric behavior of Hf_{(1-α)}Zr_{α}O₂, (0<α<1) in the orthorhombic phase includes hysteresis in the polarization, which causes history-dependent capacitance that may not be detrimental, but is not desirable for normal capacitor devices.

Hf_{(1-α)}Zr_{α}O₂, (0<α<1) in a monoclinic phase has a dielectric constant in a range from 16 to 22. The lower value of the dielectric constant of Hf_{(1-α)}Zr_{α}O₂, (0<α<1) in the monoclinic phase is not a desirable property for the purpose of use as a capacitor node dielectric material. Similarly, Hf_{(1-α)}Zr_{α}O₂, (0<α<1) in an amorphous phase has a dielectric constant in a range from 15 to 25.

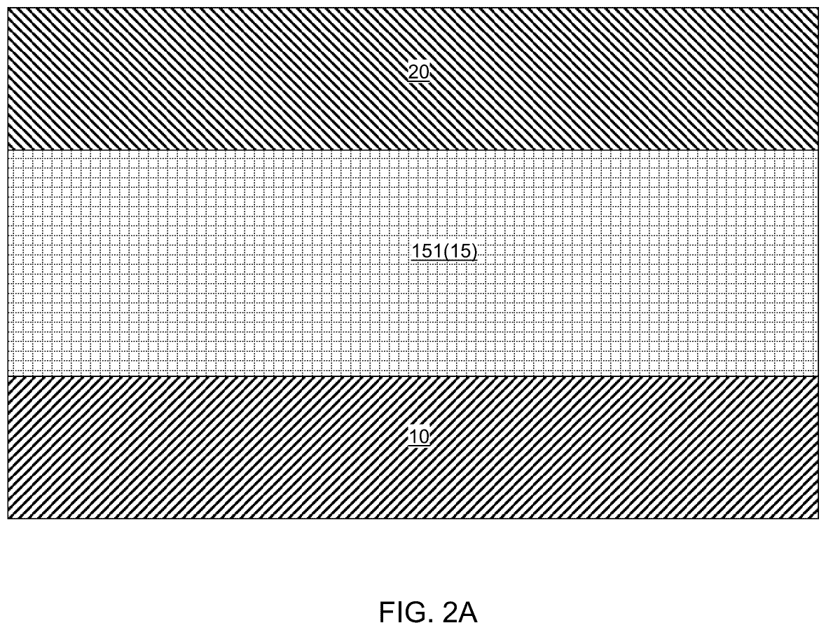

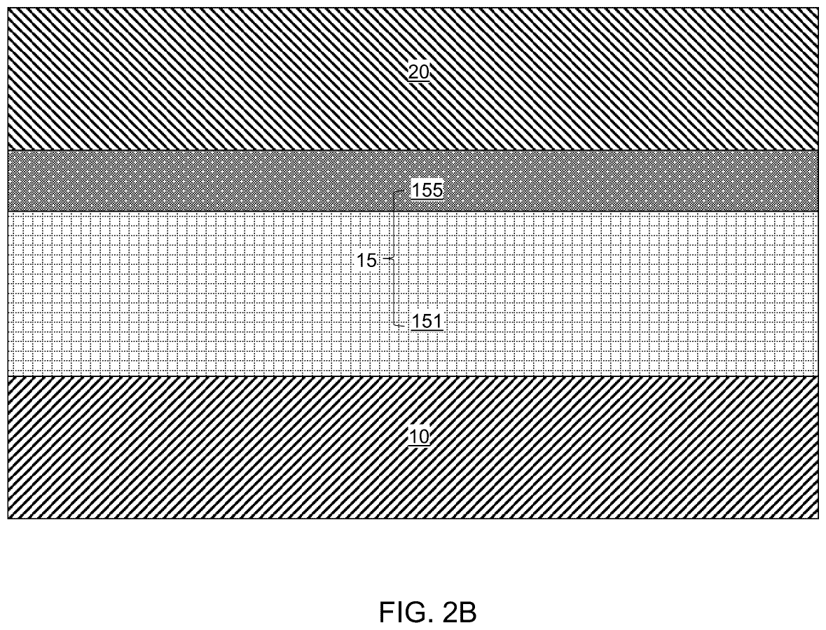

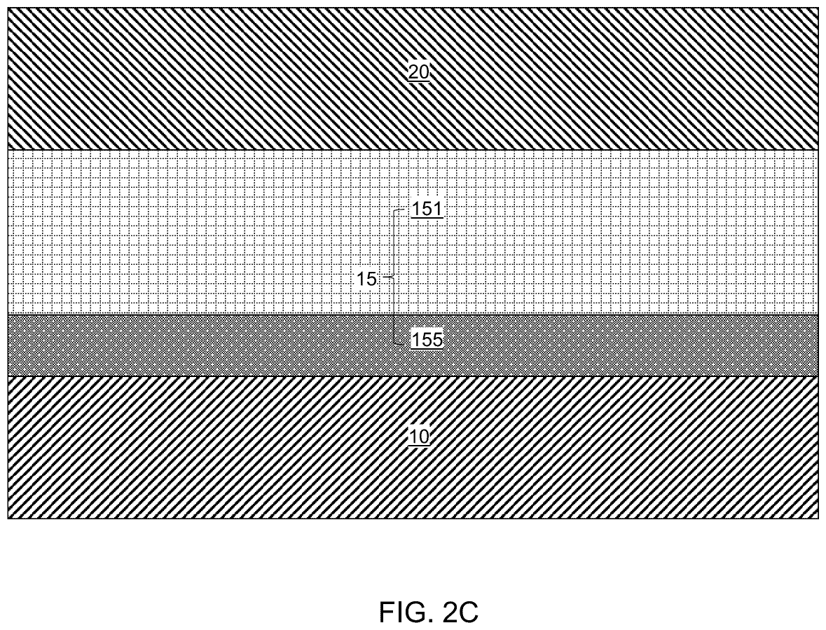

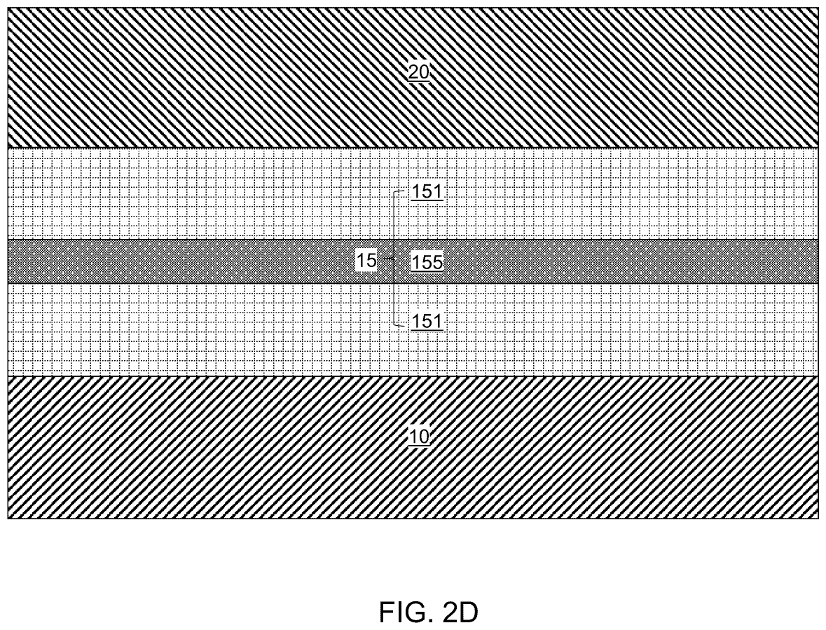

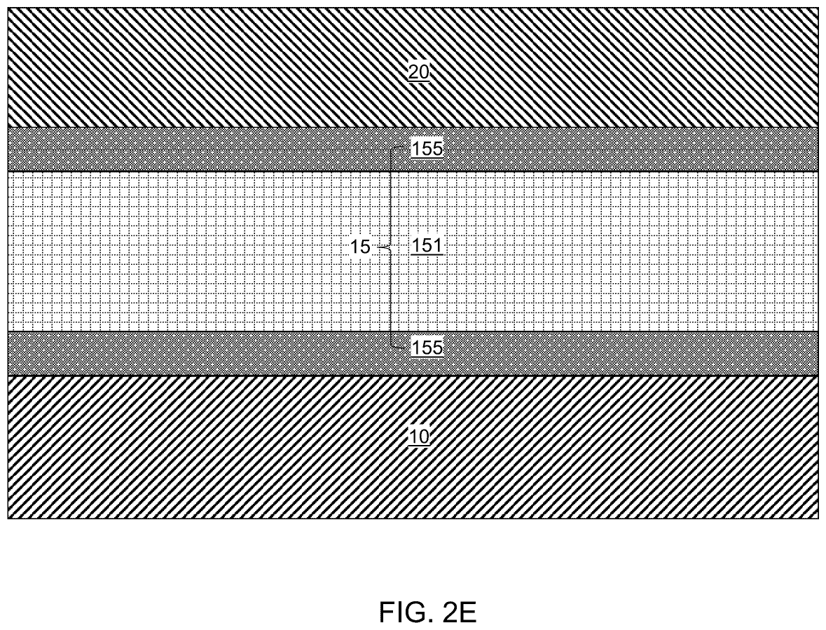

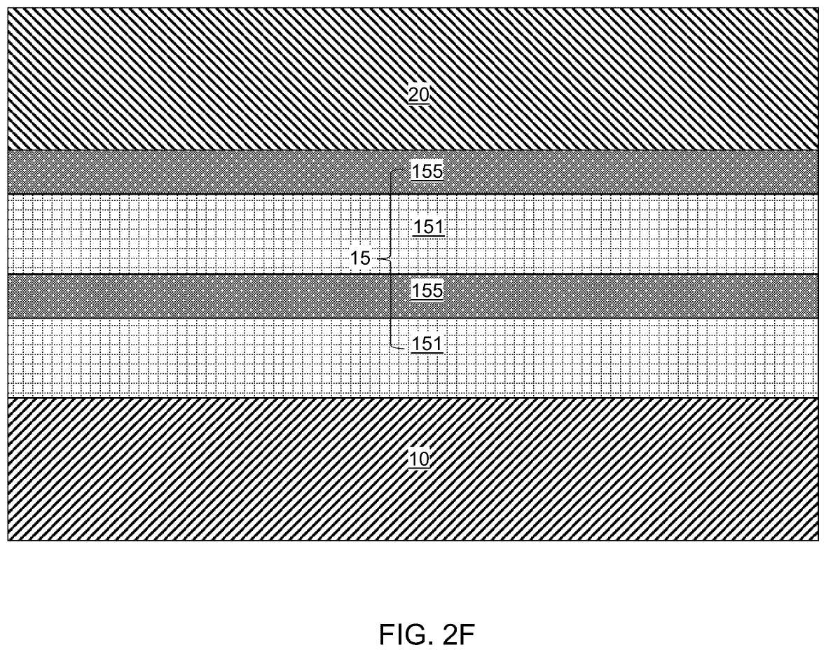

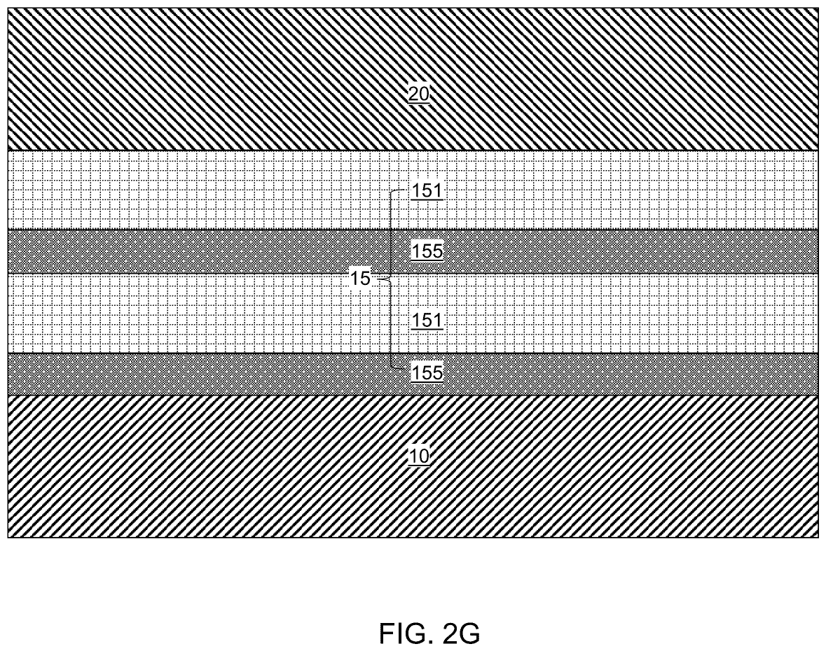

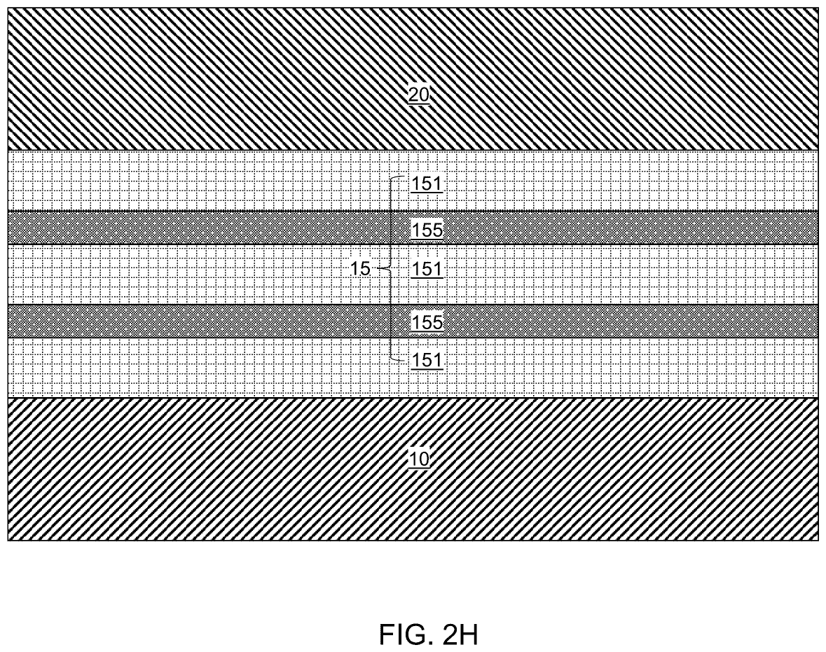

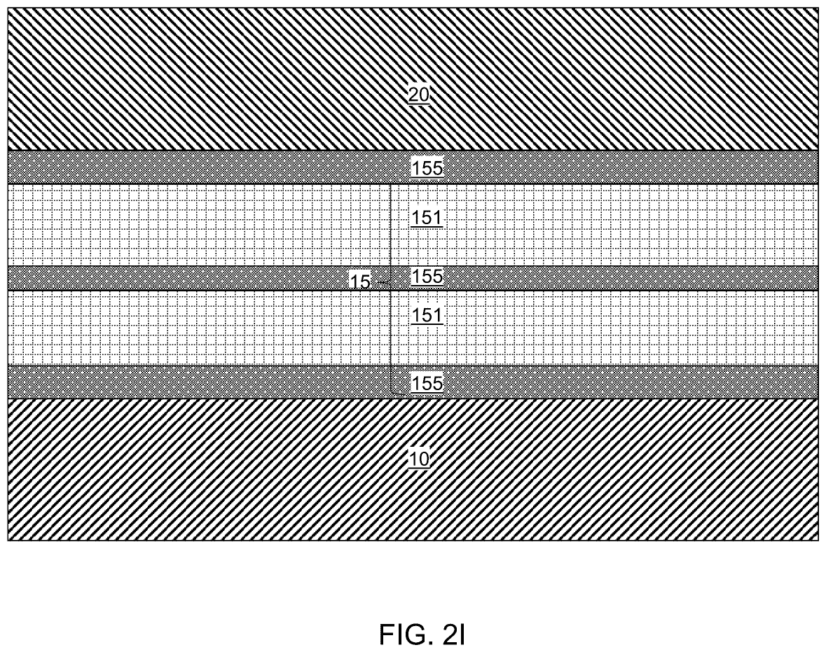

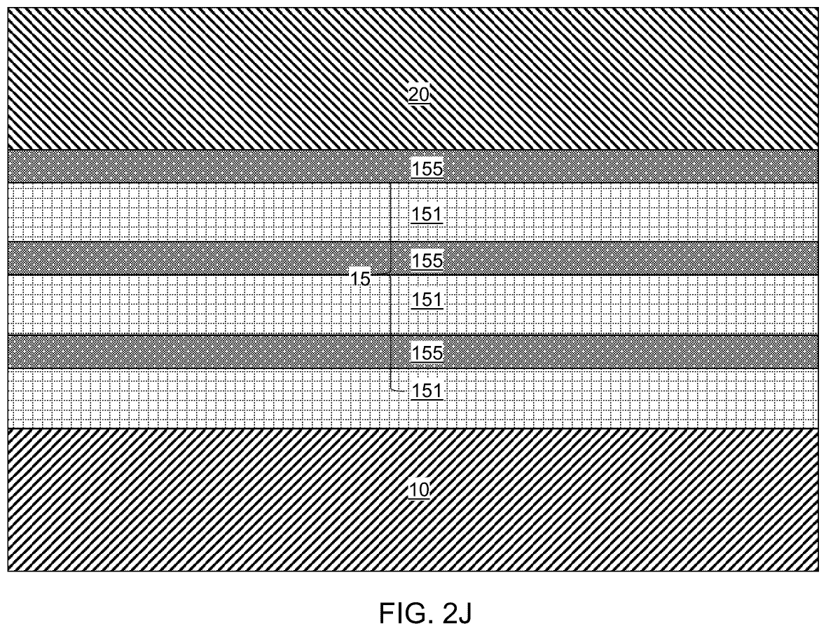

FIGS. 2A-2J are various configurations for a node dielectric layer 15 in a capacitor structure in accordance with various embodiments of the present disclosure. Referring collectively to FIGS. 2A-2J, the capacitor structure with various configurations for the node dielectric layer 15 may be formed by depositing a first metallic electrode layer 10 over a substrate (not shown); by depositing a node dielectric layer 15 comprising an amorphous hafnium zirconium oxide layer (at the time of deposition) having a material composition of Hf_{(1-α)}Zr_{α}O₂ over the first metallic electrode layer 10 such that the value of α is in a range from 0.50 to 0.90; by depositing a second metallic electrode layer 20 over the node dielectric layer 15; and by annealing the amorphous hafnium zirconium oxide layer into a crystalline hafnium zirconium oxide layer 151. In one embodiment, the node dielectric layer 15 may consist of a crystalline hafnium zirconium oxide layer 151 as illustrated in FIG. 2A. In one embodiment, the node dielectric layer 15 may comprise a layer stack of a crystalline hafnium zirconium oxide layer 151 and a high band gap dielectric layer 155 as illustrated in FIGS. 2B and 2C. In one embodiment, the node dielectric layer 15 may comprise a layer stack of a first crystalline hafnium zirconium oxide layer 151, a high band gap dielectric layer 155, and a second crystalline hafnium zirconium oxide layer 151 as illustrated in FIG. 2D. In one embodiment, the node dielectric layer 15 may comprise a layer stack of a first high band gap dielectric layer 155, a crystalline hafnium zirconium oxide layer 151, and a second high band gap dielectric layer 155 as illustrated in FIG. 2E. In one embodiment, the node dielectric layer 15 may comprise a layer stack of a first high band gap dielectric layer 155, a first crystalline hafnium zirconium oxide layer 151, a second high band gap dielectric layer 155, and a second crystalline hafnium zirconium oxide layer 151 as illustrated in FIGS. 2F and 2G. In one embodiment, the node dielectric layer 15 may comprise a layer stack of a first crystalline hafnium zirconium oxide layer 151, a first high band gap dielectric layer 155, a second crystalline hafnium zirconium oxide layer 151, a second high band gap dielectric layer 155, and a third crystalline hafnium zirconium oxide layer 151 as illustrated in FIG. 2H. In one embodiment, the node dielectric layer 15 may comprise a layer stack of a first high band gap dielectric layer 155, a first crystalline hafnium zirconium oxide layer 151, a second high band gap dielectric layer 155, a second crystalline hafnium zirconium oxide layer 151, and a third high band gap dielectric layer 155 as illustrated in FIG. 2I. In one embodiment, the node dielectric layer 15 may comprise a layer stack including at least a first high band gap dielectric layer 155, a first crystalline hafnium zirconium oxide layer 151, a second high band gap dielectric layer 155, a second crystalline hafnium zirconium oxide layer 151, a third high band gap dielectric layer 155, and a third crystalline hafnium zirconium oxide layer 151 as illustrated in FIG. 2J.

The total thickness of the node dielectric layer 15 in each configuration may be in a range from 5 nm to 50 nm, although lesser or greater thicknesses may also be used. The thickness of each crystalline hafnium zirconium oxide layer 151 may be in a range from 1 nm to 20 nm, although lesser or greater thicknesses may also be used. The thickness of each high band gap dielectric layer 155 may be in a range from 2 nm to 20 nm, although lesser or greater thicknesses may also be used. The combination of the first metallic electrode layer 10, the node dielectric layer 15, and the second metallic electrode layer 20 comprises a capacitor structure.

According to as aspect of the present disclosure, the node dielectric layer 15 comprises at least one layer of Hf_{(1-α)}Zr_{α}O₂, (0<α<1) (i.e., a crystalline hafnium zirconium oxide layer 151) in a predominantly crystalline form. Specifically, the material composition of Hf_{(1-α)}Zr_{α}O₂, (0<α<1) may be selected such that at least 95%, and more preferably at least 99%, and even more preferably 100%, of the material of Hf_{(1-α)}Zr_{α}O₂, (0<α<1) is crystallized by performing an anneal process. Further, the value for a may be selected such that the sum of the fraction of Hf_{(1-α)}Zr_{α}O₂, (0<α<1) in the tetragonal phase and the fraction of Hf_{(1-α)}Zr_{α}O₂, (0<α<1) in the orthorhombic phase is greater than 0.4, and preferably greater than 0.5, and more preferably greater than 0.6. In addition, the value for a may be selected such that the fraction of Hf_{(1-α)}Zr_{α}O₂, (0<α<1) in the tetragonal phase is greater than 0.05, and preferably greater than 0.25, and even more preferably greater than 0.40. Further, the value for a may be selected such that the fraction of Hf_{(1-α)}Zr_{α}O₂, (0<α<1) in the tetragonal phase is greater than the fraction of Hf_{(1-α)}Zr_{α}O₂, (0<α<1) in the orthorhombic phase.

Referring collectively to FIGS. 1 and 2A-2J, the fractions of the various phases of Hf_{(1-α)}Zr_{α}O₂, (0<α<1) in any crystalline hafnium zirconium oxide layer 151 of the present disclosure depends on material composition of the amorphous material of Hf_{(1-α)}Zr_{α}O₂, (0<α<1) as deposited (i.e., prior to the anneal process), the process conditions for the anneal process, and, to a lesser degree, the surface on which the material of Hf_{(1-α)}Zr_{α}O₂, (0<α<1) is located. As such, the diagram illustrated in FIG. 1 does not precisely define the fractions of the various phases or the material composition that enables a particular set of fractions for the various phases of Hf_{(1-α)}Zr_{α}O₂, (0<α<1), but describes the general parameter range for formatting the various phases and the approximate values for the fractions of the various crystalline phases. It is assumed that the anneal process is performed at a sufficiently high temperature for a sufficient duration such that the fraction of the amorphous material in Hf_{(1-α)}Zr_{α}O₂, (0<α<1) in the illustrated diagram of FIG. 1.

For the purpose of use of Hf_{(1-α)}Zr_{α}O₂, (0<α<1) within any crystalline hafnium zirconium oxide layer 151, the value for α may be selected such that the sum of the fraction of Hf_{(1-α)}Zr_{α}O₂, (0<α<1) in the tetragonal phase and the fraction of Hf_{(1-α)}Zr_{α}O₂, (0<α<1) in the orthorhombic phase is greater than 0.4, and preferably greater than 0.5, and more preferably greater than 0.6. In an illustrative example, this condition may be met by selecting the value of α in a range from 0.40 to 0.85, and preferably in a range from 0.42 to 0.82, and more preferably in a range from 0.44 to 0.79.

In addition, the value for a may be selected such that the fraction of Hf_{(1-α)}Zr_{α}O₂, (0<α<1) in the tetragonal phase is greater than 0.05, and preferably greater than 0.25, and even more preferably greater than 0.40. In an illustrative example, these condition may be met by selecting the value of α in a range from 0.65 to 0.90, and preferably in a range from 0.70 to 0.88, and even more preferably in a range from 0.75 to 0.82. Further, the value for a may be selected such that the fraction of Hf_{(1-α)}Zr_{α}O₂, (0<α<1) in the tetragonal phase is greater than the fraction of Hf_{(1-α)}Zr_{α}O₂, (0<α<1) in the orthorhombic phase. In an illustrative example, this condition may be met by selecting the value of α in a range from 0.70 to 0.95. If the fraction of Hf_{(1-α)}Zr_{α}O₂, (0<α<1) in the tetragonal phase is greater than the fraction of Hf_{(1-α)}Zr_{α}O₂, (0<α<1) in the orthorhombic phase, the effective dielectric constant of the Hf_{(1-α)}Zr_{α}O₂, (0<α<1) may be stabilized and the effect of the variation in the effective dielectric constant due to the hysteresis effect within the fraction of Hf_{(1-α)}Zr_{α}O₂, (0<α<1) in the orthorhombic phase may be reduced during operation of a capacitor.

In one embodiment, at least one of the node dielectric layers 15 comprises Hf_{(1-α)}Zr_{α}O₂, (0<α<1) such that the fraction of Hf_{(1-α)}Zr_{α}O₂, (0<α<1) in the tetragonal phase is greater than the fraction of Hf_{(1-α)}Zr_{α}O₂, (0<α<1) in the orthorhombic phase, and is greater than the fraction of Hf_{(1-α)}Zr_{α}O₂, (0<α<1) in the monoclinic phase; the fraction of Hf_{(1-α)}Zr_{α}O₂, (0<α<1) in the tetragonal phase is greater than 0.05; and the fraction of Hf_{(1-α)}Zr_{α}O₂, (0<α<1) in the tetragonal phase is greater than the fraction of Hf_{(1-α)}Zr_{α}O₂, (0<α<1) in the orthorhombic phase. In an illustrative example, this condition may be met by selecting the value of α in a range from 0.70 to 0.85.

In one embodiment, at least one of the node dielectric layers 15 comprises Hf_{(1-α)}Zr_{α}O₂, (0<α<1) such that the sum of the fraction of Hf_{(1-α)}Zr_{α}O₂, (0<α<1) in the tetragonal phase and the fraction of Hf_{(1-α)}Zr_{α}O₂, (0<α<1) in the orthorhombic phase is greater than 0.4; the fraction of Hf_{(1-α)}Zr_{α}O₂, (0<α<1) in the tetragonal phase is greater than 0.05; and the fraction of Hf_{(1-α)}Zr_{α}O₂, (0<α<1) in the tetragonal phase is greater than the fraction of Hf_{(1-α)}Zr_{α}O₂, (0<α<1) in the orthorhombic phase. In an illustrative example, this condition may be met by selecting the value of α in a range from 0.70 to 0.85.

In one embodiment, at least one of the node dielectric layers 15 comprises Hf_{(1-α)}Zr_{α}O₂, (0<α<1) such that the sum of the fraction of Hf_{(1-α)}Zr_{α}O₂, (0<α<1) in the tetragonal phase and the fraction of Hf_{(1-α)}Zr_{α}O₂, (0<α<1) in the orthorhombic phase is greater than 0.5; the fraction of Hf_{(1-α)}Zr_{α}O₂, (0<α<1) in the tetragonal phase is greater than 0.25; and the fraction of Hf_{(1-α)}Zr_{α}O₂, (0<α<1) in the tetragonal phase is greater than the fraction of Hf_{(1-α)}Zr_{α}O₂, (0<α<1) in the orthorhombic phase. In an illustrative example, this condition may be met by selecting the value of α in a range from 0.70 to 0.82.

In one embodiment, at least one of the node dielectric layers 15 comprises Hf_{(1-α)}Zr_{α}O₂, (0<α<1) such that the sum of the fraction of Hf_{(1-α)}Zr_{α}O₂, (0<α<1) in the tetragonal phase and the fraction of Hf_{(1-α)}Zr_{α}O₂, (0<α<1) in the orthorhombic phase is greater than 0.6; the fraction of Hf_{(1-α)}Zr_{α}O₂, (0<α<1) in the tetragonal phase is greater than 0.4; and the fraction of Hf_{(1-α)}Zr_{α}O₂, (0<α<1) in the tetragonal phase is greater than the fraction of Hf_{(1-α)}Zr_{α}O₂, (0<α<1) in the orthorhombic phase. In an illustrative example, this condition may be met by selecting the value of α in a range from 0.75 to 0.79.

The tetragonal phase in a hafnium zirconium oxide layer 151 in each of the configurations in FIGS. 2A-2J provides higher permittivity (i.e., a higher dielectric constant) and stable dielectric properties (without history-dependent variations in the dielectric constant that may be caused by ferroelectric properties of the orthorhombic phase). Thus, the tetragonal phase in a hafnium zirconium oxide layer 151 in each of the configurations in FIGS. 2A-2J provides superior high capacitance characteristics for the capacitor structures of the present disclosure. Further, compared to amorphous hafnium zirconium oxide material, the tetragonal phase in a hafnium zirconium oxide layer 151 offers a more consistent dielectric response and better temperature stability.

In each configuration illustrated in FIGS. 2A-2J , the sum of the fraction of hafnium zirconium oxide in the tetragonal phase and the fraction of hafnium zirconium oxide in the orthorhombic phase for each crystalline hafnium zirconium oxide layer 151 may be greater than 0.40. In one embodiment, the fraction of hafnium zirconium oxide in the tetragonal phase may be greater than the fraction of hafnium zirconium oxide in the orthorhombic phase.

In one embodiment, the fraction of hafnium zirconium oxide in the tetragonal phase is greater than the fraction of hafnium zirconium oxide in the monoclinic phase. In one embodiment, the sum of the fraction of hafnium zirconium oxide in the tetragonal phase and the fraction of hafnium zirconium oxide in the orthorhombic phase is greater than 0.50. In one embodiment, the fraction of hafnium zirconium oxide in the tetragonal phase is greater than 0.50.

Referring to FIG. 2A, a first configuration for a combination of a first metallic electrode layer 10, a node dielectric layer 15, and a second metallic electrode layer 20 is illustrated. In the first configuration, the node dielectric layer 15 consists of a crystalline hafnium zirconium oxide layer 151.

Referring collectively to FIGS. 2B-2J, the node dielectric layer 15 comprises a layer stack including at least one crystalline hafnium zirconium oxide layer 151 and at least one high band gap dielectric layer 155. As used herein, a “high band gap dielectric layer” refers to a dielectric layer having a band gap greater than 6.0 eV. Generally, if the node dielectric layer 15 contains a layer stack including at least one crystalline hafnium zirconium oxide layer 151 and at least one high band gap dielectric layer 155, the total number of the at least one crystalline hafnium zirconium oxide layer 151 may be in a range from 1 to 6, and the total number of the at least one high band gap dielectric layer 155 may be in a range from 1 to 6. The total number of the at least one crystalline hafnium zirconium oxide layer 151 may be the same as, may be greater by 1 than, or may be less by 1 than, the total number of the at least one high band gap dielectric layer 155.

In the configurations illustrated in FIGS. 2B-2J , a node dielectric layer 15 may comprise a hafnium zirconium oxide layer 151 and a high band gap dielectric layer 155. Stacking the high band gap dielectric layer 155 with the hafnium zirconium oxide layer 151 provides several advantages over using only the hafnium zirconium oxide layer 151 as the node dielectric layer 15.

According to an embodiment of the present disclosure, the inclusion of the high band gap dielectric layer 155 reduces leakage current through the node dielectric layer 15. The high band gap dielectric layer 155 may act as a barrier that suppresses tunneling effects, especially under high voltage operation, which may be advantageous given that the hafnium zirconium oxide layer 151 may include an orthorhombic phase that exhibits ferroelectric behavior, potentially contributing to leakage.

According to an embodiment of the present disclosure, the high band gap dielectric layer 155 also improves electrical isolation between nodes. By providing enhanced insulation, the high band gap dielectric layer 155 minimizes unintended cross-talk or interference, which is particularly advantageous for integrated circuits that utilize capacitors formed from the node dielectric layer 15.

According to an embodiment of the present disclosure, the combination of the high band gap dielectric layer 155 and the hafnium zirconium oxide layer 151 may create a dielectric confinement effect within the node dielectric layer 15. Such an effect improves field localization within each crystalline hafnium zirconium oxide layer 151, resulting in higher effective capacitance without dramatic increases in leakage current. This configuration may be advantageous for metal-insulator-metal (MIM) capacitors, where maximizing capacitance per unit area is desired.

According to an embodiment of the present disclosure, the high band gap dielectric layer 155 may assist in stabilizing desirable crystalline phases, such as the tetragonal phase within the hafnium zirconium oxide layer 151, during the operation of the node dielectric layer 15. By appropriately selecting a high band gap dielectric material that does not chemically interact with hafnium zirconium oxide, the high band gap dielectric layer 155 may mitigate unwanted phase transitions, such as transitions from the tetragonal to monoclinic phase. Suppression of phase changes in the hafnium zirconium oxide layer 151 provides the benefit of a stable and high dielectric constant for the node dielectric layer 15.

According to an embodiment of the present disclosure, stacking the high band gap dielectric layer 155 with the hafnium zirconium oxide layer 151 may also reduce the impact of ferroelectric instabilities within the orthorhombic phase. Such instabilities may cause undesired switching effects that could affect the performance of capacitors. The high band gap dielectric layer 155 provides enhanced dielectric isolation, thereby improving the stability of the node dielectric layer 15.

According to an embodiment of the present disclosure, the stacking of the high band gap dielectric layer 155 with the hafnium zirconium oxide layer 151 allows for optimization of the capacitance-voltage (C-V) characteristics of the node dielectric layer 15. Each high band gap dielectric layer 155 provides the ability to fine-tune the overall C-V response of the dielectric stack, resulting in a more linear characteristic across a range of operating voltages, which is highly desirable in many electronic applications.

According to an embodiment of the present disclosure, each high band gap dielectric layer 155 contributes to improved thermal and voltage stability of the node dielectric layer 15. The high band gap dielectric materials used for the high band gap dielectric layer 155 typically have good thermal and electrical stability, which enhances the reliability of the node dielectric layer 15 under high temperature and high electric field conditions.

According to an embodiment of the present disclosure, the inclusion of the high band gap dielectric layer 155 in combination with the hafnium zirconium oxide layer 151 allows the properties of the node dielectric layer 15 to be tailored for specific applications. For example, the combination may be optimized to achieve low leakage current, high breakdown voltage, or specific C-V characteristics. This flexibility is advantageous for developing node dielectric layers that meet the specific requirements of different applications, such as RF switches, power amplifiers, and digital circuits.

According to an embodiment of the present disclosure, each high band gap dielectric layer 155 may serve as an insulating layer with superior barrier properties. Each high band gap dielectric layer 155 may reduce leakage currents, and may improve insulation properties of the semiconductor structure, contributing to its reliability. The combination of the high band gap dielectric layer 155 with the hafnium zirconium oxide layer 151 maintains a higher capacitance while contributing to enhanced thermal and voltage stability.

According to an embodiment of the present disclosure, each high band gap dielectric layer 155 has a band gap greater than 6 eV. For example, each high band gap dielectric layer 155 may comprise a material such as silicon oxide, aluminum oxide, magnesium oxide, calcium oxide, or zirconium silicate. Each high band gap dielectric layer 155 may be deposited by an atomic layer deposition process or a chemical vapor deposition process. A high band gap in the high band gap dielectric layer 155 assists in suppressing electron tunneling and minimizing leakage currents, which is advantageous for high-voltage or high-temperature applications. A dielectric material with a lower band gap could lead to increased leakage, making it less suitable for use as a node dielectric, where both high capacitance and effective electrical isolation are desired.

In one embodiment, the high band gap dielectric layer 155 may be formed of silicon dioxide (SiO₂). The high band gap dielectric layer 155 composed of silicon dioxide, when combined with the hafnium zirconium oxide layer 151, improves reliability in terms of thermal stability and minimizes leakage.

In one embodiment, the high band gap dielectric layer 155 may be composed of aluminum oxide (Al₂O₃). Aluminum oxide provides high dielectric strength and thermal stability, which, in instances in which aluminum oxide is combined with the hafnium zirconium oxide layer 151, the aluminum oxide enhances capacitance while maintaining effective insulation.

In one embodiment, the high band gap dielectric layer 155 may be composed of magnesium oxide (MgO), which offers high thermal conductivity and dielectric properties. The combination of the high band gap dielectric layer 155 with the hafnium zirconium oxide layer 151 may be beneficial for high-frequency applications where efficient thermal management is desired.

In one embodiment, the high band gap dielectric layer 155 may be composed of calcium oxide (CaO). In instances in which the calcium oxide is combined with the hafnium zirconium oxide layer 151, the high band gap dielectric layer 155 composed of calcium oxide may provide structural stability and improved insulation, especially in instances in which the node dielectric layer 15 is thick.

In one embodiment, the high band gap dielectric layer 155 may be composed of zirconium silicate (ZrSiO₄). According to an embodiment of the present disclosure, combining the high band gap dielectric layer 155 composed of zirconium silicate with the hafnium zirconium oxide layer 151 provides structural stability and resistance to breakdown at high temperatures, making the combination suitable for applications in harsh environments.

According to an embodiment of the present disclosure, stacking of at least one high band gap dielectric layer 155 with at least one hafnium zirconium oxide layer 151 may be utilized to provide dielectric confinement effects. The dielectric confinement effects may increase capacitance and reduce leakage by isolating the hafnium zirconium oxide layer 151 with the high band gap dielectric layer 155, which serves as an effective barrier. This layered configuration enhances overall device performance by balancing high capacitance with effective insulation.

The crystallographic phase of the high band gap dielectric layer 155 may vary based on the material used. In one embodiment, the high band gap dielectric layer 155 may be composed of silicon dioxide, which may be present in an amorphous phase. In one embodiment, the high band gap dielectric layer 155 may be composed of aluminum oxide, which may be present in a crystalline hexagonal structure. In one embodiment, the high band gap dielectric layer 155 may be composed of magnesium oxide or calcium oxide, both of which may be found in crystalline cubic phases. In one embodiment, the high band gap dielectric layer 155 may be composed of zirconium silicate, which may form in a crystalline tetragonal structure. According to an embodiment of the present disclosure, selecting an appropriate material and phase for the high band gap dielectric layer 155 contributes to the effectiveness of the combined node dielectric structure.

In some embodiments, one or more of the hafnium zirconium oxide layer 151 may comprise hafnium zirconium oxide portions in the tetragonal phase and may additionally comprise ferroelectric domains composed of hafnium zirconium oxide portions in the orthorhombic phase. In other words, ferroelectric domains may be collaterally present within a hafnium zirconium oxide layer 151 of the present disclosure. According to an aspect of the present disclosure, one or more high band gap dielectric layers 155 may be utilized to reduce ferroelectric polarization switching in the hafnium zirconium oxide layer 151, which comprises both tetragonal and orthorhombic phases. By disposing at least one high band gap dielectric layer 155 on a respective hafnium zirconium oxide layer 151, a multi-domain state may be formed within the ferroelectric material that is an orthorhombic fraction of the hafnium zirconium oxide layer 151. The multi-domain state may reduce remanent polarization, and may mitigate polarization switching effects. Each high band gap dielectric layer 155 may contribute to the increase in the depolarization field, which alters the polarization dynamics of the ferroelectric material within a subset of the crystallographic grains in the hafnium zirconium oxide layer(s) 151. Increase in the depolarization field reduces domain switching, stabilizes polarization states, and effectively suppresses the volatility associated with the orthorhombic phase's ferroelectric behavior, thereby providing consistent performance in capacitive applications involving the node dielectric layer 15.

According to an aspect of the present disclosure, the thickness of the Hf_{(1-α)}Zr_{α}O₂ material of the present disclosure in the node dielectric layer 15 may be controlled to increase the fraction of the tetragonal phase after the anneal process. In such embodiments, two or more hafnium zirconium oxide layers 151 may be present within the node dielectric layer 15. During the research leading to the present disclosure, inventors of the present disclosure observed that thinner amorphous Hf_{(1-α)}Zr_{α}O₂ layers tend to crystalline with a higher fraction of the tetragonal phase relative to thick amorphous Hf_{(1-α)}Zr_{α}O₂ layers. Without being bound by any particular theory, it is believed that the increase in the fraction of tetragonal phase in thin annealed Hf_{(1-α)}Zr_{α}O₂ layers may be due to surface energy effects. According to an aspect of the present disclosure, use of multiple hafnium zirconium oxide layers 151 in lieu of a single hafnium zirconium oxide layer 151 may increase the fraction of the tetragonal phase within the multiple hafnium zirconium oxide layers 151 relative to the fraction of the tetragonal phase within the single hafnium zirconium oxide layer 151.

According to an aspect of the present disclosure, the node dielectric layer 15 may comprise a superlattice (i.e., a periodic repetition of a unit structure including at least two layers) of at least two instances of a unit layer stack including a hafnium zirconium oxide layer 151 and a high band gap dielectric layer 155. The total number of repetitions of the unit layer stack may be in a range from 2 to 6, although a greater number of repetitions may also be used. Superlattices may provide better control over charge distribution and reduce leakage by alternating high-k materials (comprising the hafnium zirconium oxide layers 151) with high band gap insulators (comprising the high band gap dielectric layers 155). The superlattice configuration may also enhance mechanical stability and further reduce thermal stress.

In some embodiments, the surface of the first metallic electrode layer 10 or the surface of the second metallic electrode layer 20 may be in direct contact with a hafnium zirconium oxide layer 151. In this embodiment, a catalytic metallic material that is conducive to formation of the tetragonal phase of a crystalline hafnium zirconium oxide material may be used to help stabilize the tetragonal phase in the hafnium zirconium oxide layer 151 by providing appropriate surface conditions. For example, a thin platinum layer or a thin ruthenium layer having a thickness in a range from 1 nm to 30 nm may be used as a catalytic surface layer for the first metallic electrode layer 10 and/or for the second metallic electrode layer 20. The catalytic surface layer(s) may suppress and/or minimize any phase transition from the tetragonal phase to a less desirable phase (such as a monoclinic phase) during operation of the capacitor structure.

For configurations in which the node dielectric layer 15 includes a layer stack including at least one hafnium zirconium oxide layer 151 and at least one high band gap dielectric layer 155 (such as configurations illustrated in FIGS. 2B-2J), a capacitor structure may be formed by depositing a first metallic electrode layer 10 over a substrate; by depositing a node dielectric layer 15 comprising a layer stack containing at least a first amorphous hafnium zirconium oxide layer having a material composition of Hf_{(1-α)}Zr_{α}O₂ and a first high band gap dielectric layer 155 over the first metallic electrode layer 10 such that the value of α is in a range from 0.50 to 0.90, and the first high band gap dielectric layer 155 comprises a first dielectric material having a first band gap greater than 6 eV; by depositing a second metallic electrode layer 20 over the node dielectric layer 15; and by annealing the first amorphous hafnium zirconium oxide layer into a first crystalline hafnium zirconium oxide layer 151.

In one embodiment, the first crystalline hafnium zirconium oxide layer 151 comprises tetragonal phase portions and orthorhombic phase portions including a ferroelectric material; and the first high band gap dielectric layer 155 reduces ferroelectric polarization switching of the ferroelectric material by increasing a depolarization field. In one embodiment, the layer stack contains a second amorphous hafnium zirconium oxide layer that is formed on first high band gap dielectric layer 155 having a material composition of Hf_{(1-β)}Zr_{β}O₂ over the first metallic electrode layer 10, wherein a value of β is in a range from 0.50 to 0.90. In one embodiment, the layer stack contains a second high band gap dielectric layer 155 that is formed on the first amorphous hafnium zirconium oxide layer and comprises a second dielectric material having a second band gap greater than 6 eV. In one embodiment, a second amorphous hafnium zirconium oxide layer which has a material composition of Hf_{(1-β)}Zr_{β}O₂, and is formed over the first high band gap dielectric layer 155, wherein a value of α is in a range from 0.50 to 0.90; and a second high band gap dielectric layer 155 that is formed over the second amorphous hafnium zirconium oxide layer metallic electrode layer, wherein the second high band gap dielectric layer 155 comprises a second dielectric material having a second band gap greater than 6 eV.

Generally, the compositional modulation, the control of crystalline phase distribution, and the stacking order of the at least one crystalline hafnium zirconium oxide layer 151 and at least one high band gap dielectric layer 155 may be selected to reduce the leakage current through the capacitor structure, and to increase the thermal stability of the node dielectric layer 15. Further, a superlattice structure and/or band gap engineering may be used to increase the stability of the reliability of the node dielectric layer 15.

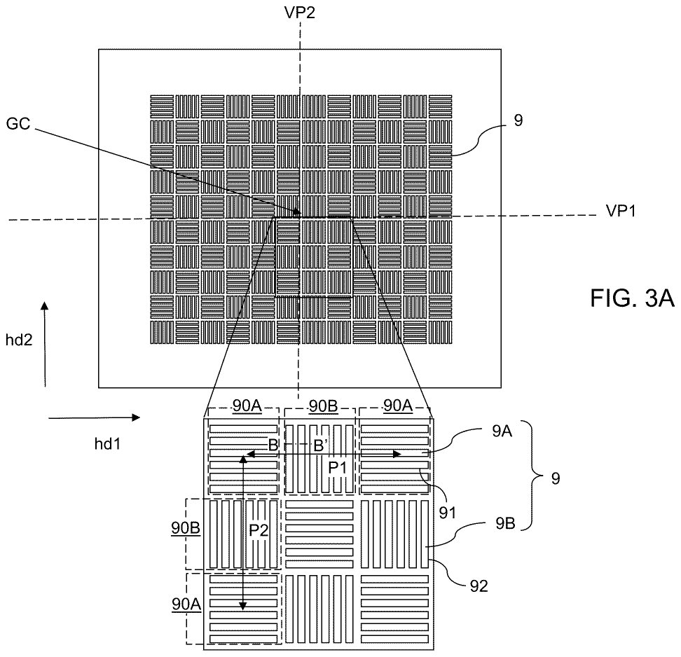

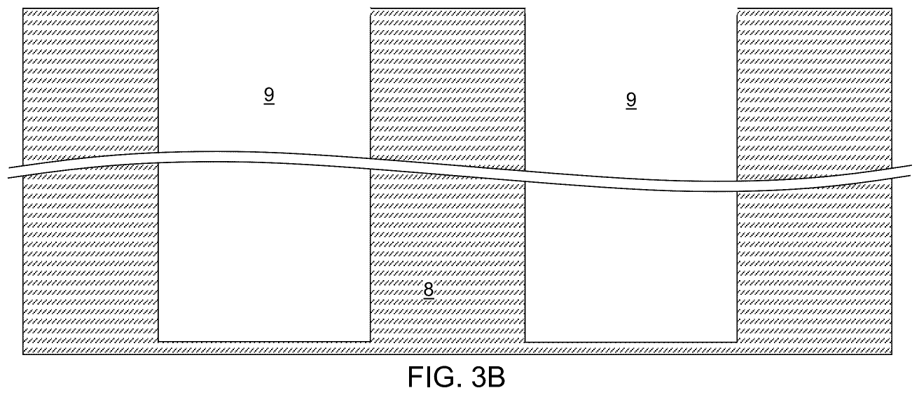

The capacitor structure described with reference to FIGS. 2A-2J may be implemented in various embodiments. FIGS. 3A-11C illustrate various embodiments of the capacitor structure of the present disclosure that uses at least one instance of the capacitor structure (10, 15, 20) described with reference to FIGS. 2A-2J .

Referring to FIGS. 3A and 3B, a first embodiment structure according to an embodiment of the present disclosure is illustrated, which comprises a substrate 8 having a planar top surface. The substrate 8 may be a semiconductor substrate including a semiconductor material, and may have a thickness of at least 10 microns. In one embodiment, the substrate 8 may include a commercially available semiconductor wafer that may be diced into semiconductor dies after formation of deep trenches. For example, the substrate 8 may include a semiconductor substrate including single crystalline silicon and having a thickness in a range from 500 microns to 1,500 microns, although thicker or thinner substrates may be used.

Deep trenches 9 vertically extending into the substrate 8 may be formed by forming a patterned etch mask layer on the front side surface of the substrate 8. The pattern in the patterned etch mask layer may be transferred the into an upper portion of the substrate 8. An optional pad dielectric layer (not shown) such as a silicon oxide pad layer may be formed on the front side surface, i.e., the top surface, of the substrate 8 prior to formation of the patterned etch mask layer. In an exemplary embodiment, the pad dielectric layer may include a silicon oxide layer having a thickness in a range from 20 nm to 100 nm, although thicker or thinner pad dielectric layers may be used.

The patterned etch mask layer may include a silicon nitride layer or a borosilicate glass (BSG) layer having a thickness in a range from 200 nm to 600 nm, although different materials and/or lesser or greater thicknesses may also be used for the optional pad dielectric layer and the patterned etch mask layer. The patterned etch mask layer may be formed by depositing a blanket etch mask layer, forming a lithographically patterned photoresist layer over the blanket etch mask layer, and by transferring the pattern in the lithographically patterned photoresist layer through the blanket etch mask layer using an anisotropic etch process such as a reactive ion etch process.

An anisotropic etch process may be performed to transfer the pattern in the patterned etch mask layer through an upper portion of the substrate 8 to form the deep trenches 9. For example, a reactive ion etch process using a combination of gases including HBr, NF₃, O₂, and SF₆ may be used to form the deep trenches 9. The depth of the deep trenches 9 may be in a range from 2 micron to 20 microns, such as from 3 microns to 10 microns, although deeper or shallower trenches may be used. The horizontal cross-sectional shape of each deep trench 9 may have a shape of a circle, an ellipse, a rectangle, a rounded rectangle, an annulus having an inner periphery and an outer periphery of various shapes, or of any two-dimensional shape that defines an enclosed volume. Generally, at least one deep trench 9 extending downward from a top surface of the substrate may be formed in the substrate 8. The at least one deep trench 9 may comprise a plurality of deep trenches 9 having a depth that is greater than 2 microns.

In one embodiment, each of the deep trenches 9 may be laterally elongated with a uniform width. A predominant portion (such as more than 50% of the entire area) of each deep trench 9 may have a width that is sufficient to accommodate vertically-extending portions of all metallic electrode layers and at least two node dielectric layers to be subsequently formed. For example, a predominant portion of each deep trench 9 may have a width that is sufficient to accommodate vertically-extending portions of at least three metallic electrode layers and at least two node dielectric layers. In an illustrative example, a predominant portion of each deep trench 9 may have a width that is in a range from 50 nm to 1,000 nm, although lesser or greater widths may also be used.

In one embodiment, first-type deep trenches 9A and second-type deep trenches 9B may be formed into an upper portion of the substrate 8. The first-type deep trenches 9A may have first lengthwise sidewalls 91 that laterally extend along a first horizontal direction hd1 and the second-type deep trenches 9B may have second lengthwise sidewalls 92 that laterally extend along a second horizontal direction hd2 that is different from the first horizontal direction hd1. In one embodiment, the second horizontal direction hd2 may be perpendicular to the first horizontal direction hd1.

In one embodiment, each of the first-type deep trenches 9A and the second-type deep trenches 9B may have a length-to-width ratio in a range from 3 to 30. In one embodiment, each of the first-type deep trenches 9A and the second-type deep trenches 9B has a depth-to-width ratio in a range from 10 to 200. In one embodiment, each of the first-type deep trenches 9A and the second-type deep trenches 9B has a depth in a range from 2 micron to 20 microns.

In one embodiment, clusters 90A of subsets of the first-type deep trenches 9A and clusters 90B of subsets of the second-type deep trenches 9B laterally alternate along at least one direction that is selected from the first horizontal direction hd1 and the second horizontal direction hd2. The second horizontal direction hd2 may be perpendicular to the first horizontal direction hd1. In one embodiment, the clusters 90A of subsets of the first-type deep trenches 9A and clusters 90B of subsets of the second-type deep trenches 9B laterally alternate along the first horizontal direction hd1 and along the second horizontal direction hd2. In the illustrated example, each cluster of a subset of the first-type deep trenches 9A includes six first-type deep trenches 9A, and each cluster of a subset of the second-type deep trenches 9B includes six second-type deep trenches 9B.

In one embodiment, the first-type deep trenches 9A and the second-type deep trenches 9B comprise a two-dimensional array of deep trenches 9 in which the first-type deep trenches 9A are arranged as a first two-dimensional periodic array and the second-type deep trenches 9B are arranged as a second two-dimensional periodic array that is interlaced with the first two-dimensional periodic array. In one embodiment, each of the first two-dimensional periodic array and the second two-dimensional periodic array has a first periodic pitch P1 along the first horizontal direction hd1 and has a second periodic pitch hd2 along the second horizontal direction hd2. In one embodiment, the second two-dimensional periodic array may be laterally offset along the first horizontal direction hd1 by one half of the first periodic pitch P1, and may be laterally offset along the second horizontal direction hd2 by one half of the second periodic pitch P2.

The photoresist layer may be removed prior to the anisotropic etch process that forms the deep trenches 9, or may be consumed during the anisotropic etch process that forms the deep trenches 9. The patterned etch mask layer and the optional dielectric pad layer may be subsequently removed, for example, by a respective isotropic etch process such as a wet etch process.

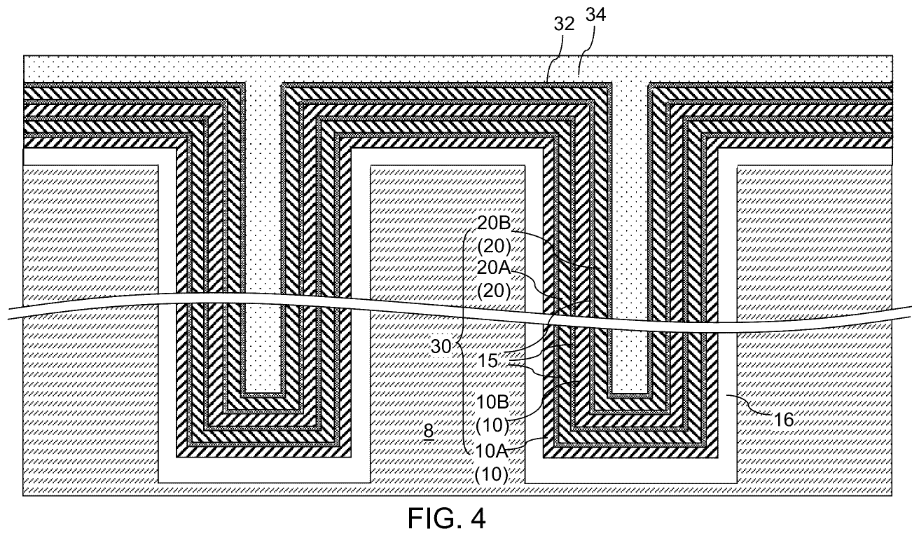

FIG. 4 is a vertical cross-sectional view of a region of the first embodiment structure after formation of a layer stack including at least three metallic electrode layers interlaced with at least two node dielectric layers according to an embodiment of the present disclosure. Referring to FIG. 4, a dielectric liner 16 may be formed on the physically exposed surface of the semiconductor substrate 8 including the top surface of the semiconductor substrate 8 and sidewalls of the deep trenches 9. The dielectric liner 16 may include a dielectric material that provides electrical isolation between the deep trench capacitors to be subsequently formed and the substrate 8. For example, the dielectric liner 16 may include silicon oxide, silicon nitride, silicon oxynitride, and/or a dielectric metal oxide. Other suitable materials within the contemplated scope of disclosure may also be used. In an illustrative example, the dielectric liner 16 may include a silicon oxide layer formed by thermal oxidation of surface portions of the substrate 8 that includes silicon. The thickness of the dielectric liner 16 may be in a range from 4 nm to 100 nm, although lesser or greater thicknesses may also be used.

An alternating layer stack 30 of metallic electrode layers (10A, 20A, 10B, 20B) and node dielectric layers 15 may be formed by a respective conformal deposition process. The alternating layer stack 30 may include at least three metallic electrode layers (10A, 20A, 10B, 20B) interlaced with at least two node dielectric layers 15, and continuously extending over the top surface of the semiconductor substrate 8 and into each of the at least one deep trench 9. The alternating layer stack 30 may continuously extends into each deep trench 9. A cavity may be present in an unfilled volume each the deep trench 9. Generally, the at least three metallic electrode layers (10A, 20A, 10B, 20B) and the at least two node dielectric layers 15 are deposited by a respective conformal deposition process.

The metallic electrode layers (10A, 20A, 10B, 20B) may comprise at least one first metallic electrode layer 10 that functions as a first electrode of a capacitor structure, and at least one second metallic electrode layer 20 that functions as a second electrode of the capacitor structure. Each first metallic electrode layer 10 in FIG. 4 may be the same as a first metallic electrode layer 10 in any of FIGS. 2A-2J . Each second metallic electrode layer 10 in FIG. 4 may be the same as a second metallic electrode layer 20 in any of FIGS. 2A-2J . The at least one first metallic electrode layer 10 may comprise a plurality of first metallic electrode layers (10A, 10B). The at least one second metallic electrode layer 20 may comprise a plurality of second metallic electrode layers (10A, 10B). While the first embodiment structure is illustrated in a configuration that includes two first metallic electrode layers (10A, 10B) and two second metallic electrode layers (20A, 20B), the total number of the metallic electrode layers (10A, 20A, 10B, 20B) may be generally in a range from 2 to 20, although a greater number may also be used.

Each of the metallic electrode layers (10A, 20A, 10B, 20B) may include a metallic material, which may comprise, and/or consist essentially of, a conductive metallic nitride, an elemental metal, or an intermetallic alloy. In one embodiment, each metallic electrode layer (10A, 20A, 10B, 20B) comprises, and/or consists essentially of, a conductive metallic nitride material, which may be a metallic diffusion barrier material. For example, each metallic electrode layer (10A, 20A, 10B, 20B) may include, and/or may consist essentially of, a conductive metallic nitride material such as TiN, TaN, or WN. Other suitable materials within the contemplated scope of disclosure may also be used.

Use of a metallic diffusion barrier material for the metallic electrode layers (10A, 20A, 10B, 20B) may be advantageous because diffusion of metallic elements through the node dielectric layers 15 and/or through the dielectric liner 16 may cause deleterious effects for deep trench capacitors. Each metallic electrode layer (10A, 20A, 10B, 20B) may be formed by a conformal deposition process such as chemical vapor deposition (CVD) or atomic layer deposition (ALD). The thickness of each metallic electrode layer (10A, 20A, 10B, 20B) may be in a range from 5 nm to 50 nm, such as from 10 nm to 30 nm, although lesser or greater thicknesses may also be used. In one embodiment, each metallic electrode layer (10A, 20A, 10B, 20B) may have the same material composition and the same thickness. In another embodiment, each metallic electrode layer (10A, 20A, 10B, 20B) may have the same material composition but have different thicknesses. In yet another embodiment, each metallic electrode layer (10A, 20A, 10B, 20B) may have different material compositions and may have the same thickness. In yet another embodiment, each metallic electrode layer (10A, 20A, 10B, 20B) may have different material compositions and may have different thicknesses.

According to an aspect of the present disclosure, each node dielectric layer 15 in the first embodiment structure of FIG. 4 may have any configuration illustrated in FIGS. 2A-2J , and may be formed using processes described with reference to FIGS. 2A-2J. Each hafnium zirconium oxide layer may be deposited as an amorphous material layer. An anneal process may be performed after formation of the node dielectric layers 15 to convert each amorphous hafnium zirconium oxide layer into a respective crystalline hafnium zirconium oxide layer 151. The anneal process may comprise a rapid thermal anneal process or a furnace anneal process.

Patterned portions of each first metallic electrode layer (10A, 10B) may be subsequently used to form a primary electrode assembly that functions as a primary node, i.e., a first node, of a deep trench capacitor, and patterned portions of each second metallic electrode layer (20A, 20B) may be subsequently used to form a complementary electrode assembly that functions as a complementary node, i.e., a second node, of the deep trench capacitor. The total number of the metallic electrode layers (10A, 20A, 10B, 20B), the thicknesses of the metallic electrode layers (10A, 20A, 10B, 20B), and the width of the deep trenches 9 may be selected such that a predominant portion (i.e., more than 50%) of the entire volume of each deep trench 9 may be filled with the alternating layer stack 30 without completely filling the deep trench 9.

A capping dielectric material layer 32 and a dielectric fill material layer 34 may be optionally deposited over the alternating layer stack 30. The capping dielectric material layer 32 may include a same dielectric material as the node dielectric layers 15, and may have a thickness in a range from 1 nm to 20 nm, such as from 3 nm to 12 nm, although lesser or greater thicknesses may also be used.

The dielectric fill material layer 34 may be deposited on the capping dielectric material layer 32 or on the alternating layer stack 30 to fill the volumes of cavities that remain in the deep trenches 9. In one embodiment, the dielectric fill material layer 34 comprises, and/or consists essentially of, undoped silicate glass or a doped silicate glass.

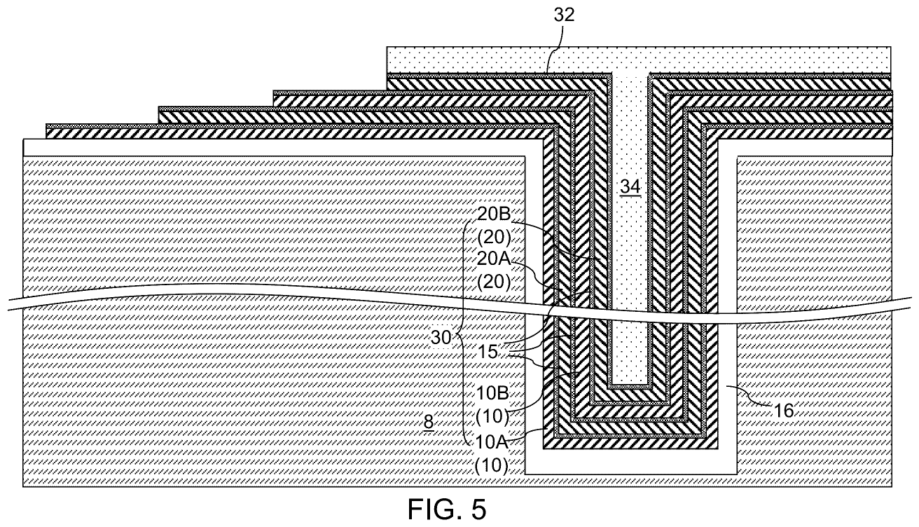

FIG. 5 is a vertical cross-sectional view of a peripheral region of the first embodiment structure after patterning the layer stack according to an embodiment of the present disclosure. Referring to FIG. 5, a trimmable mask layer may be applied over the dielectric fill material layer 34, and may be lithographically patterned to cover the area of the deep trenches 9. The entire periphery of the trimmable mask layer may be located outside the area of the deep trenches 9. A first set of etch processes may be performed to etch unmasked portions of the dielectric fill material layer 34, the optional capping dielectric material layer 32, and the topmost layer selected from the metallic electrode layers (10A, 10B, 20A, 20B). The first set of etch processes may include a set of wet etch processes.

Subsequently, the trimmable mask layer may be trimmed to laterally recess the periphery of the trimmable mask layer and to increase the area unmasked by the trimmable mask layer. A second set of etch processes may be performed to etch unmasked portions of the dielectric fill material layer 34, the optional capping dielectric material layer 32, unmasked portions of the topmost one of the node dielectric layers 15, and unmasked underlying portions of the metallic electrode layers (10A, 10B, 20A, 20B).

The trimming of the trimmable mask layer and additional sets of etch processes may be repeated to provide stepped surfaces for the metallic electrode layers (10A, 10B, 20A, 20B). The trimmable mask layer may be subsequently removed, for example, by ashing or by dissolution in a solvent.

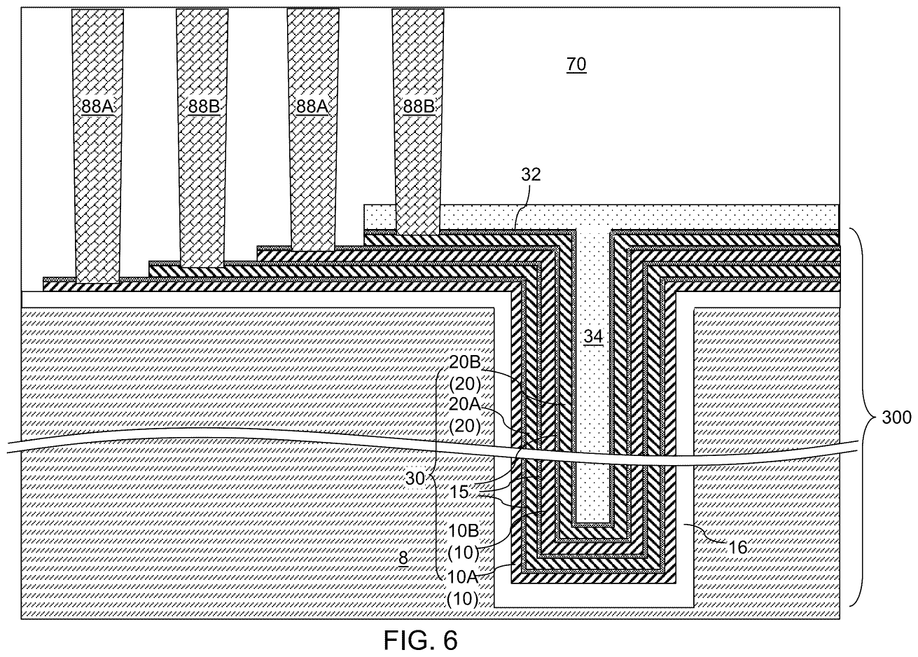

FIG. 6 is a vertical cross-sectional view of a region of the first embodiment structure after formation of a planarization dielectric layer and contact via structures according to an embodiment of the present disclosure. Referring to FIG. 6, a planarizable dielectric material or a self-planarizing dielectric material may be deposited over the alternating layer stack (10A, 10B, 20A, 20B) and the dielectric fill material layer 34 to form a contact-level dielectric layer 70. The contact-level dielectric layer 70 may have a thickness in a range from 100 nm to 2,000 nm, although lesser or greater thicknesses may also be used.

Contact via structures (88A, 88B) may be formed through the contact-level dielectric layer 70 on a respective one of the metallic electrode layers (10A, 10B, 20A, 20B). Each of the at least three metallic electrode layers (10A, 10B, 20A, 20B) may be contacted by a respective contact via structure (88A, 88B) formed within the contact-level dielectric layer 70, which overlies the horizontally-extending portion of the dielectric fill material layer 34.

Additional dielectric material layers (not shown) and additional metal interconnect structures (not shown) may be formed over the contact-level dielectric layer 70 and the contact via structures (88A, 88B) as known in the art. Bonding structures such as copper bonding pads and/or copper bonding pillar structures may be formed over the metal interconnect structures as known in the art. Subsequently, the first embodiment structure may be diced into a plurality of semiconductor dies, which may be a capacitor die that may be attached to another semiconductor die. Each semiconductor die may include a deep trench capacitor 300.

The capacitor structure in the first embodiment structure includes at least one laterally alternating sequence of clusters 90A of first-type deep trenches 9A and clusters 90B of second-type deep trenches 9B. The first-type deep trenches 9A have lengthwise sidewalls that laterally extend along the first horizontal direction hd1 and the second-type deep trenches 9B have lengthwise sidewalls that laterally extend along the second horizontal direction hd2. The alternation of lengthwise directions of the deep trenches 9 may homogenize along the different azimuthal directions (i.e., along horizontal directions) the mechanical stress generated by the vertically-extending portions of the alternating layer stack 30, and thus, reduces stress-induced deformation of a semiconductor die that includes the deep trench capacitor of the first embodiment structure. In one embodiment, each layer within the alternating layer stack 30 comprises a horizontally-extending portion that overlies a top surface of the substrate 8 and vertically-extending portions that protrude downward into a respective one of the first-type deep trenches 9A and second-type deep trenches 9B.

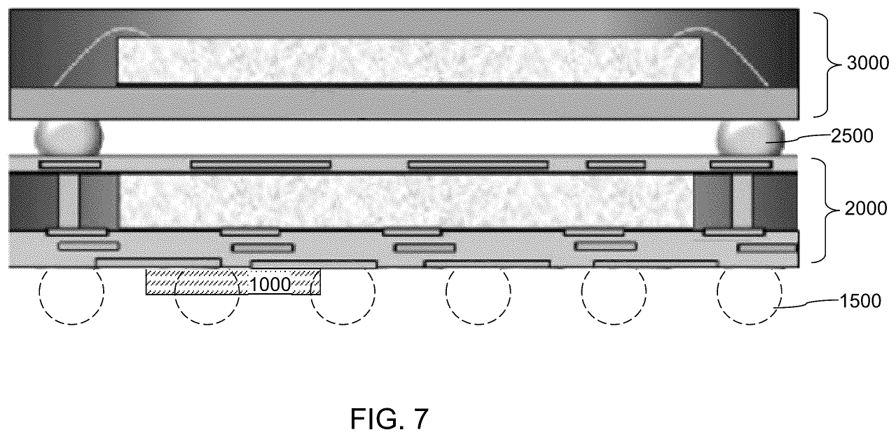

Referring to FIG. 7, an exemplary semiconductor structure incorporating a capacitor structure described with reference to FIGS. 3A-6 is illustrated. In one embodiment, first semiconductor die 1000 may be formed by dicing the first embodiment structures of FIG. 6. The first semiconductor die 1000 comprises a diced portion of the substrate 8 and a capacitor structure 300.

Generally, a first semiconductor die 1000 may be provided which incorporate the first embodiment structure of FIG. 6. The first semiconductor die 1000 may be attached to the bottom side of a second semiconductor die 2000. For example, the first semiconductor die 1000 may be bonded to a second semiconductor die 2000 that comprises semiconductor devices therein. The capacitor structure 300 may be electrically connected to the semiconductor devices through bonding pads or solder material portions.

For example, the second semiconductor die 2000 may be a system-on-a-chip (SoC) die 2000, which may be bonded to an integrated fan-out package on package (InFO PoP) die 3000 via an array of solder balls 2500. The second semiconductor die 2000 may be bonded to another module, such as a printed circuit board (PCB) via another array of solder balls 1500. The deep trench capacitor(s) in the semiconductor die 1000 may be used to stabilize the power supply system in the second semiconductor die 2000.

In the first embodiment structure, the substrate 8 on which a capacitor structure is formed may comprise a semiconductor substrate. During manufacture of the first embodiment structure, a vertically-extending trench (such as a deep trench 9) may be formed in an upper portion of the semiconductor substrate. In this embodiment, each of the first metallic electrode layer 10, the node dielectric layer 15, and the second metallic electrode layer 20 comprises a respective vertically-extending portion that is formed within a volume of the vertically-extending trench.

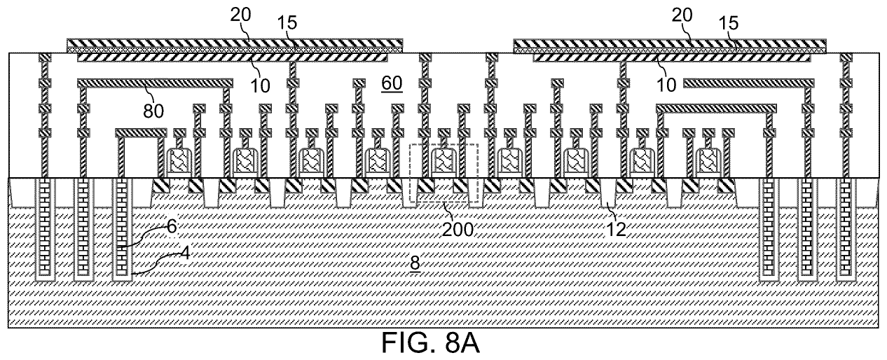

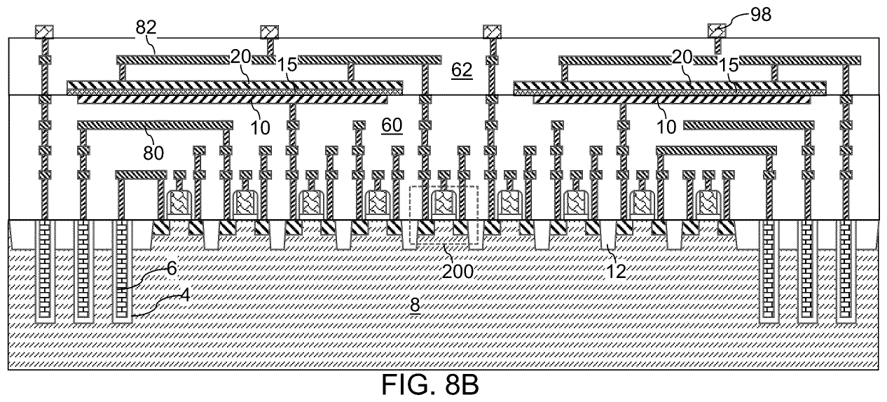

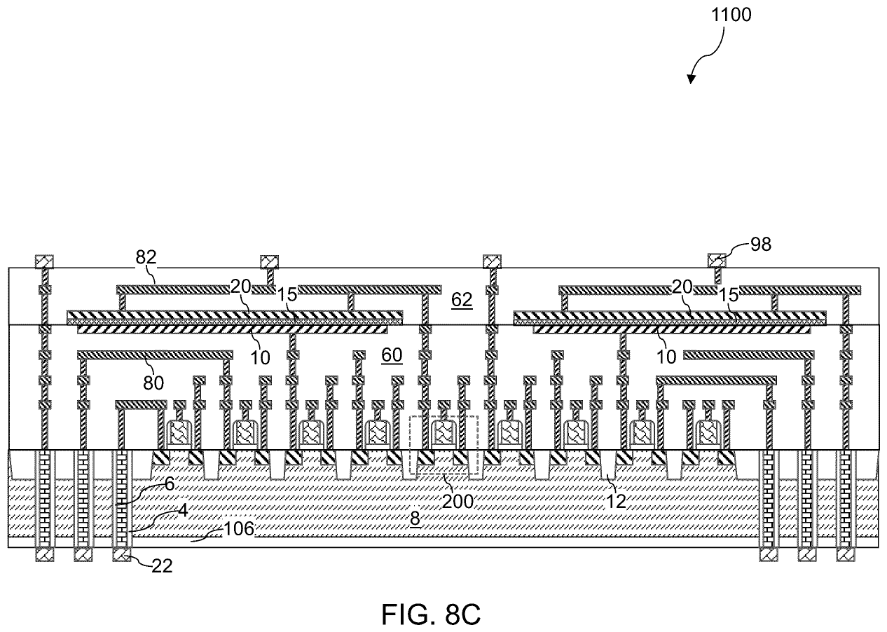

FIGS. 8A-8C are sequential vertical cross-sectional views of a second embodiment structure including a capacitor structure during a sequence of manufacturing steps according to an embodiment of the present disclosure.

Referring to FIG. 8A, the second embodiment structure comprises a substrate 8, which may comprise a semiconductor substrate such as a semiconductor wafer as known in the art. Shallow trench isolation structures 12 may be formed in an upper portion of the substrate 8. Deep trenches having a lateral dimension in a range from 0.5 micron to 20 microns and having a depth in a range from 5 microns to 60 microns may be formed in an upper portion of the substrate 8. The deep trenches may be formed through the shallow trench isolation structures 12, and are herein referred to as through-substrate deep trenches. The through-substrate deep trenches may be filled with combinations of a dielectric liner 4 and a through-substrate via structure 6.

Various semiconductor devices 200 such as field effect transistors may be formed on the top surface of the substrate 8. First dielectric material layers 60 having first metal interconnect structures 80 formed therein may be formed over the substrate 8. The first dielectric material layers 60 may comprise any interlayer dielectric (ILD) material known in the art. The first metal interconnect structures 80 may comprise metal line structures and metal via structures. The total number of the metal line levels within the first metal interconnect structures 80 may be in a range from 1 to 20.

A first metallic electrode layer 10 may be formed over a top surface of a topmost layer among the first dielectric material layers 60. In some embodiments, a portion of the top surface of the topmost layer among the first dielectric material layers 60 may be vertically recessed prior to formation of the first metallic electrode layer 10. The first metallic electrode layer 10 may comprise the same material as described in preceding embodiments. A node dielectric layer 15 may be deposited over each first metallic electrode layer 10. The node dielectric layer 15 in the second exemplary structure may be the same as any node dielectric layer 15 in the various configurations described with reference to FIGS. 2A-2J. A second metallic electrode layer 20 may be subsequently formed over the node dielectric layer 15. The second metallic electrode layer 20 may comprise the same material as described in preceding embodiments. Each of the at least one amorphous hafnium zirconium oxide layer in the node dielectric layer 15 may be annealed into a respective crystalline hafnium zirconium oxide layer 151 by performing a laser anneal process in which a laser beam irradiates each of the at least one amorphous hafnium zirconium oxide layer. The laser anneal process may be performed prior to, or after, formation of the second metallic electrode layer 20. A capacitor structure (10, 15, 20) may be formed.

Referring to FIG. 8B, second dielectric material layers 62 having second metal interconnect structures 82 formed therein may be formed over the capacitor structure 20. The second dielectric material layers 62 may comprise any interlayer dielectric (ILD) material known in the art. The second metal interconnect structures 82 may comprise metal line structures and metal via structures. The total number of the metal line levels within the second metal interconnect structures 82 may be in a range from 1 to 20. Metallic bonding structures 98 may be formed over the second metal interconnect structures 82.

Referring to FIG. 8C, the substrate 8 may be thinned from the backside, for example, by grinding, polishing, an anisotropic etch process, or an isotropic etch process. The backside surfaces of the through-substrate via structures 6 may be exposed upon thinning of the substrate 8. The backside surface of the substrate 8 may be further recessed, and a backside insulating layer 106 may be formed on the recessed backside surface of the substrate 8. Backside bonding structures 22 may be formed on the backside surfaces of the through-substrate via structures 6. The second embodiment structure may be diced into a plurality of semiconductor dies 1100, each of which may be a semiconductor structure including a respective set of at least one capacitor structure (10, 15, 20).

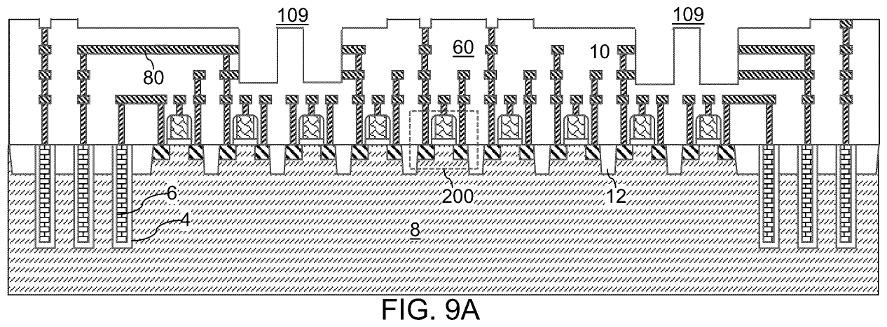

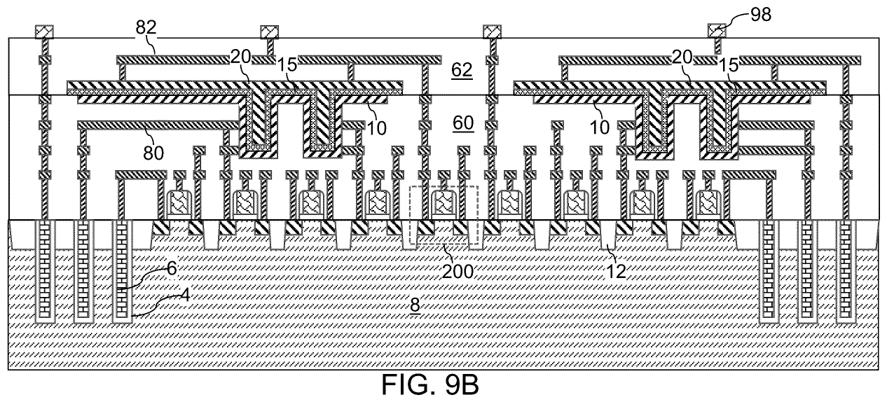

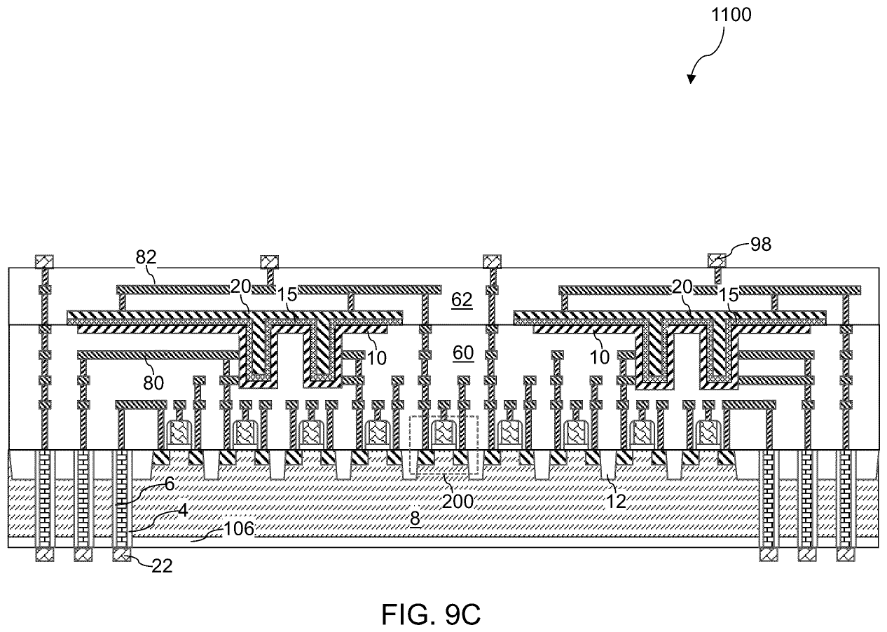

FIGS. 9A-9C are sequential vertical cross-sectional views of a third embodiment structure including a capacitor structure during a sequence of manufacturing steps according to an embodiment of the present disclosure.

Referring to FIG. 9A, the third embodiment structure comprises a substrate 8, which may comprise a semiconductor substrate such as a semiconductor wafer as known in the art. Shallow trench isolation structures 12 may be formed in an upper portion of the substrate 8. Deep trenches having a lateral dimension in a range from 0.5 micron to 20 microns and having a depth in a range from 5 microns to 60 microns may be formed in an upper portion of the substrate 8. The deep trenches may be formed through the shallow trench isolation structures 12, and are herein referred to as through-substrate deep trenches. The through-substrate deep trenches may be filled with combinations of a dielectric liner 4 and a through-substrate via structure 6.

Various semiconductor devices 200 such as field effect transistors may be formed on the top surface of the substrate 8. First dielectric material layers 60 having first metal interconnect structures 80 formed therein may be formed over the substrate 8. The first dielectric material layers 60 may comprise any interlayer dielectric (ILD) material known in the art. The first metal interconnect structures 80 may comprise metal line structures and metal via structures. The total number of the metal line levels within the first metal interconnect structures 80 may be in a range from 1 to 20.

At least one contoured trench 109 may be formed within the first dielectric material layers 60. As used herein, a “contoured trench” refers to a trench including a non-planar bottom surface, i.e., a contoured bottom surface. In one embodiment, each contoured trench 109 may comprise a horizontally-extending portion and a vertically-extending portion that is adjoined to the horizontally-extending portion. According to an aspect of the present disclosure, at least one sidewall of one or more of the first metal interconnect structures 80 may be physically exposed around a vertically-extending portion of each contoured trench 109. In one embodiment, a plurality of sidewalls of the first metal interconnect structures 80 located at different levels may be physically exposed to a vertically-extending portion of a contoured trench 109. A subset of the first metal interconnect structures 80 having a respective physically exposed sidewall may be subsequently used to provide electrical contacts to first metallic electrode layers of capacitor structures to be subsequently formed.

Referring to FIG. 9B, a first metallic electrode layer 10 may be formed on a contoured bottom surface of each contoured trench 109. In one embodiment, a first metallic electrode layer 10 may deposited directly on each physically exposed sidewall of the first metal interconnect structures 80 around each contoured cavity 109. A node dielectric layer 15 may be deposited over each first metallic electrode layer 10. The node dielectric layer 15 in the second exemplary structure may be the same as any node dielectric layer 15 in the various configurations described with reference to FIGS. 2A-2J. A second metallic electrode layer 20 may be subsequently formed over the node dielectric layer 15. The second metallic electrode layer 20 may comprise the same material as described in preceding embodiments.

Each of the at least one amorphous hafnium zirconium oxide layer in the node dielectric layer 15 may be annealed into a respective crystalline hafnium zirconium oxide layer 151 by performing a laser anneal process in which a laser beam irradiates each of the at least one amorphous hafnium zirconium oxide layer. The laser anneal process enables local heating of the node dielectric layers 15 without significantly heating adjacent first dielectric material layers 60, which may be prone to thermal damage. The first metallic electrode layers 10 may function as a thermal buffer structure during the laser anneal process. In some embodiments, physically exposed surfaces of the first dielectric material layers 60 may comprise an inorganic dielectric material (such as silicon oxide or silicon nitride) that is resistant to exposure to elevated temperatures. The laser anneal process may be performed prior to, or after, formation of the second metallic electrode layer 20. According to an aspect of the present disclosure, the lateral dimensions of each of the vertically-extending portions of the contoured trenches 109 may be selected to enable irradiation of a laser beam to bottom portions of the node dielectric layer 15 that are formed at the bottom of the contoured trenches 109. In one embodiment, the lateral dimensions of the vertically-extending portions of the contoured trenches 109 may be greater than the wavelength of the laser beam, which may be in a range from 400 nm to 1,600 nm. A capacitor structure (10, 15, 20) may be formed.

Subsequently, second dielectric material layers 62 having second metal interconnect structures 82 formed therein may be formed over the capacitor structure 20. The second dielectric material layers 62 may comprise any interlayer dielectric (ILD) material known in the art. The second metal interconnect structures 82 may comprise metal line structures and metal via structures. The total number of the metal line levels within the second metal interconnect structures 82 may be in a range from 1 to 20. Metallic bonding structures 98 may be formed over the second metal interconnect structures 82.

Referring to FIG. 9C, the substrate 8 may be thinned from the backside, for example, by grinding, polishing, an anisotropic etch process, or an isotropic etch process. The backside surfaces of the through-substrate via structures 6 may be exposed upon thinning of the substrate 8. The backside surface of the substrate 8 may be further recessed, and a backside insulating layer 106 may be formed on the recessed backside surface of the substrate 8. Backside bonding structures 22 may be formed on the backside surfaces of the through-substrate via structures 6. The second embodiment structure may be diced into a plurality of semiconductor dies 1100, each of which may be a semiconductor structure including a respective set of at least one capacitor structure (10, 15, 20).

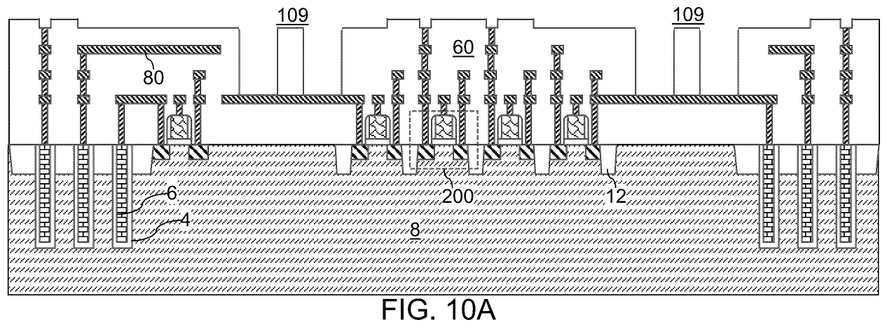

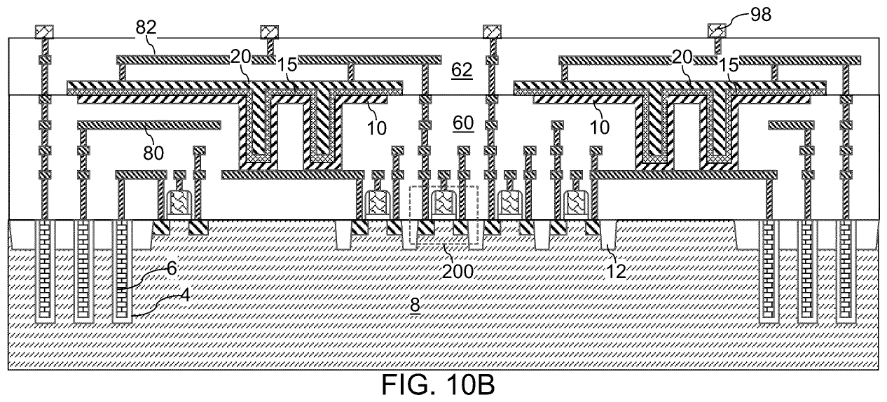

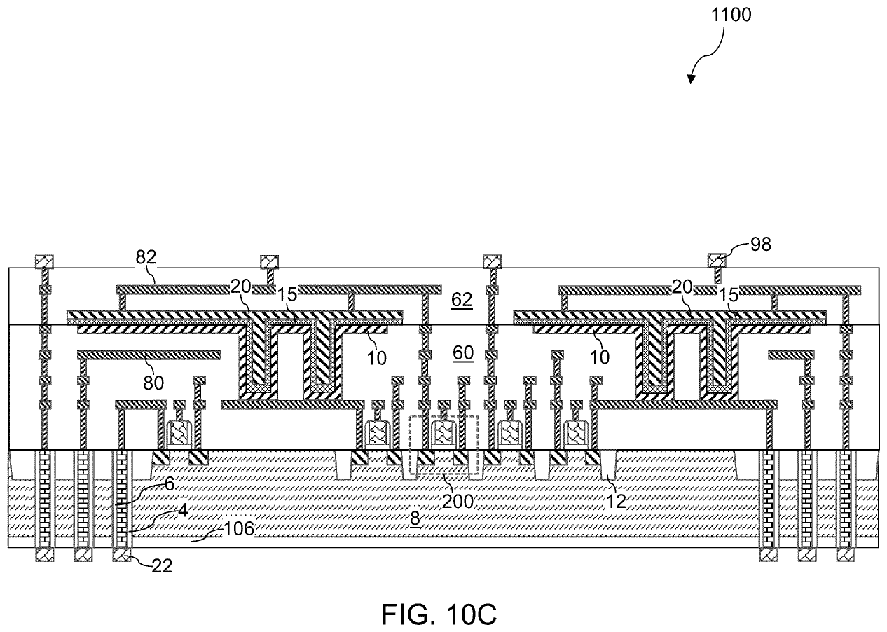

FIGS. 10A-10C are sequential vertical cross-sectional views of a fourth embodiment structure including a capacitor structure during a sequence of manufacturing steps according to an embodiment of the present disclosure.

Referring to FIG. 10A, the fourth embodiment structure comprises a substrate 8, which may comprise a semiconductor substrate such as a semiconductor wafer as known in the art. Shallow trench isolation structures 12 may be formed in an upper portion of the substrate 8. Deep trenches having a lateral dimension in a range from 0.5 micron to 20 microns and having a depth in a range from 5 microns to 60 microns may be formed in an upper portion of the substrate 8. The deep trenches may be formed through the shallow trench isolation structures 12, and are herein referred to as through-substrate deep trenches. The through-substrate deep trenches may be filled with combinations of a dielectric liner 4 and a through-substrate via structure 6.

Various semiconductor devices 200 such as field effect transistors may be formed on the top surface of the substrate 8. First dielectric material layers 60 having first metal interconnect structures 80 formed therein may be formed over the substrate 8. The first dielectric material layers 60 may comprise any interlayer dielectric (ILD) material known in the art. The first metal interconnect structures 80 may comprise metal line structures and metal via structures. The total number of the metal line levels within the first metal interconnect structures 80 may be in a range from 1 to 20.

At least one contoured trench 109 may be formed within the first dielectric material layers 60. According to an aspect of the present disclosure, at least one top surface of one or more of the first metal interconnect structures 80 may be physically exposed at the bottom of a vertically-extending portion of each contoured trench 109. A subset of the first metal interconnect structures 80 having a respective physically exposed top surface may be subsequently used to provide electrical contacts to first metallic electrode layers of capacitor structures to be subsequently formed.

Referring to FIG. 10B, a first metallic electrode layer 10 may be formed on a contoured bottom surface of each contoured trench 109. In one embodiment, a first metallic electrode layer 10 may deposited directly on each physically exposed top surface of the first metal interconnect structures 80 at the bottom of each contoured cavity 109. A node dielectric layer 15 may be deposited over each first metallic electrode layer 10. The node dielectric layer 15 in the second exemplary structure may be the same as any node dielectric layer 15 in the various configurations described with reference to FIGS. 2A-2J. A second metallic electrode layer 20 may be subsequently formed over the node dielectric layer 15. The second metallic electrode layer 20 may comprise the same material as described in preceding embodiments.

Each of the at least one amorphous hafnium zirconium oxide layer in the node dielectric layer 15 may be annealed into a respective crystalline hafnium zirconium oxide layer 151 by performing a laser anneal process in which a laser beam irradiates each of the at least one amorphous hafnium zirconium oxide layer. The laser anneal process may be performed prior to, or after, formation of the second metallic electrode layer 20. According to an aspect of the present disclosure, the lateral dimensions of each of the vertically-extending portions of the contoured trenches 109 may be selected to enable irradiation of a laser beam to bottom portions of the node dielectric layer 15 that are formed at the bottom of the contoured trenches 109. In one embodiment, the lateral dimensions of the vertically-extending portions of the contoured trenches 109 may be greater than the wavelength of the laser beam, which may be in a range from 400 nm to 1,600 nm. A capacitor structure (10, 15, 20) may be formed.

Subsequently, second dielectric material layers 62 with second metal interconnect structures 82 formed therein may be formed over the capacitor structure 20. The second dielectric material layers 62 may comprise any interlayer dielectric (ILD) material known in the art. The second metal interconnect structures 82 may comprise metal line structures and metal via structures. The total number of the metal line levels within the second metal interconnect structures 82 may be in a range from 1 to 20. Metallic bonding structures 98 may be formed over the second metal interconnect structures 82.

Referring to FIG. 10C, the substrate 8 may be thinned from the backside, for example, by grinding, polishing, an anisotropic etch process, or an isotropic etch process. The backside surfaces of the through-substrate via structures 6 may be exposed upon thinning of the substrate 8. The backside surface of the substrate 8 may be further recessed, and a backside insulating layer 106 may be formed on the recessed backside surface of the substrate 8. Backside bonding structures 22 may be formed on the backside surfaces of the through-substrate via structures 6. The second embodiment structure may be diced into a plurality of semiconductor dies 1100, each of which may be a semiconductor structure including a respective set of at least one capacitor structure (10, 15, 20).

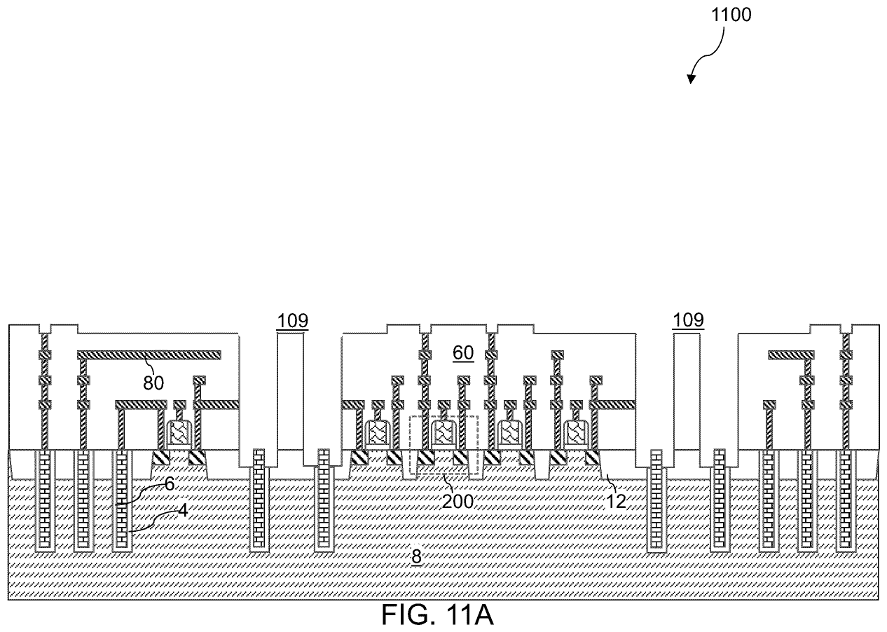

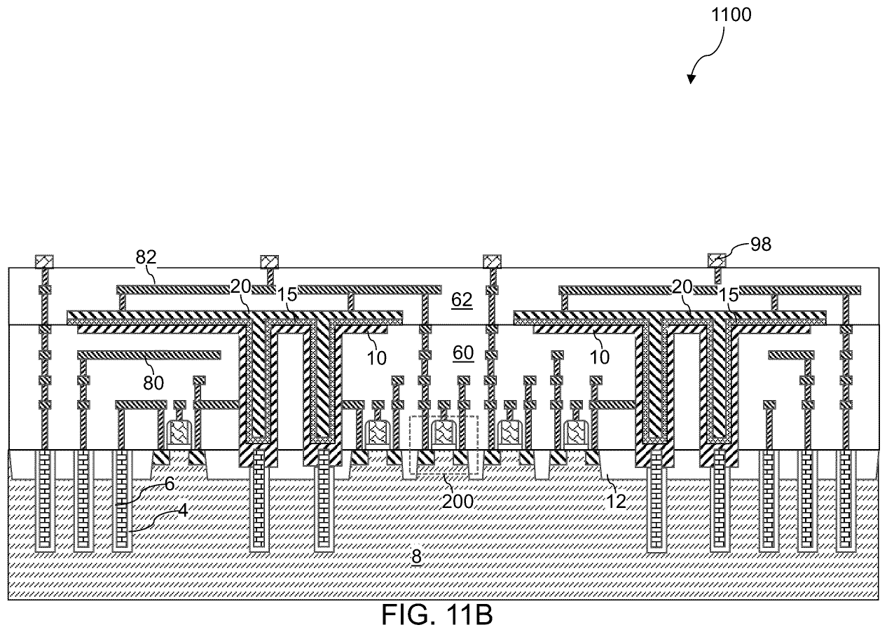

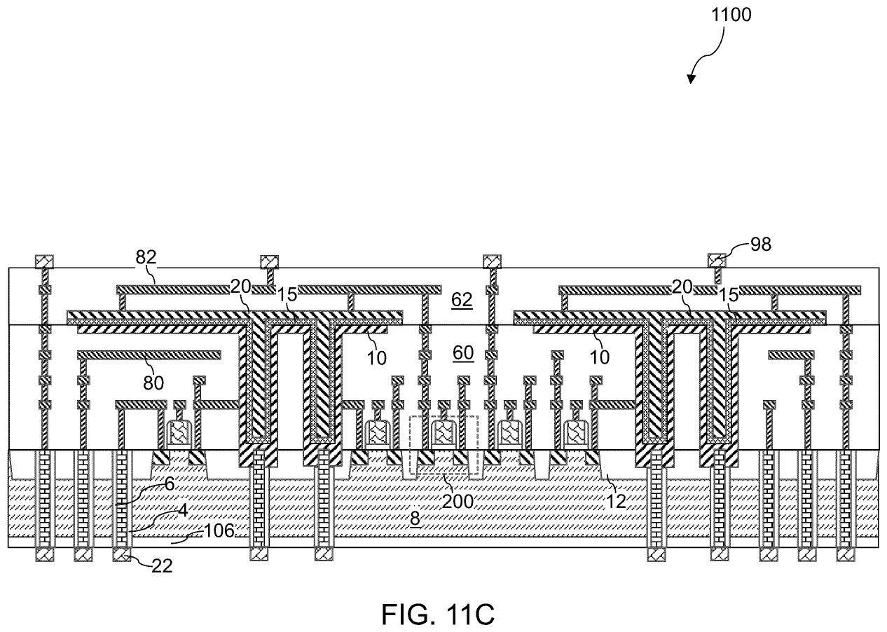

FIGS. 11A-11C are sequential vertical cross-sectional views of a fifth embodiment structure including a capacitor structure during a sequence of manufacturing steps according to an embodiment of the present disclosure.

Referring to FIG. 11A, the fifth embodiment structure comprises a substrate 8, which may comprise a semiconductor substrate such as a semiconductor wafer as known in the art. Shallow trench isolation structures 12 may be formed in an upper portion of the substrate 8. Deep trenches having a lateral dimension in a range from 0.5 micron to 20 microns and having a depth in a range from 5 microns to 60 microns may be formed in an upper portion of the substrate 8. The deep trenches may be formed through the shallow trench isolation structures 12, and are herein referred to as through-substrate deep trenches. The through-substrate deep trenches may be filled with combinations of a dielectric liner 4 and a through-substrate via structure 6.

Various semiconductor devices 200 such as field effect transistors may be formed on the top surface of the substrate 8. First dielectric material layers 60 with first metal interconnect structures 80 formed therein may be formed over the substrate 8. The first dielectric material layers 60 may comprise any interlayer dielectric (ILD) material known in the art. The first metal interconnect structures 80 may comprise metal line structures and metal via structures. The total number of the metal line levels within the first metal interconnect structures 80 may be in a range from 1 to 20.

At least one contoured trench 109 may be formed within the first dielectric material layers 60. According to an aspect of the present disclosure, the vertically-extending portions of the at least one contoured trench 109 may vertically extend into an upper portion of the shallow trench isolation structures 12 around a subset of the through-substrate via structures 6. The top surface and an upper segment of a sidewall of one or more of the through-substrate via structures 6 may be physically exposed at the bottom of a vertically-extending portion of each contoured trench 109. In one embodiment, a plurality of through-substrate via structures 6 may comprise a respective top surface of a respective sidewall surface segment that are exposed to a respective vertically-extending portion of a contoured trench 109. A subset of the through-substrate via structures 6 having a respective physically exposed top surface and a respective physically exposed sidewall surface segment may be subsequently used to provide electrical contacts to first metallic electrode layers of capacitor structures to be subsequently formed.

Referring to FIG. 11B, a first metallic electrode layer 10 may be formed on a contoured bottom surface of each contoured trench 109. In one embodiment, a first metallic electrode layer 10 may deposited directly on each physically exposed top surface and each physically exposed sidewall surface segment of one or more through-substrate via structures 6 at the bottom of each contoured cavity 109. A node dielectric layer 15 may be deposited over each first metallic electrode layer 10. The node dielectric layer 15 in the second exemplary structure may be the same as any node dielectric layer 15 in the various configurations described with reference to FIGS. 2A-2J. A second metallic electrode layer 20 may be subsequently formed over the node dielectric layer 15. The second metallic electrode layer 20 may comprise the same material as described in preceding embodiments.

Each of the at least one amorphous hafnium zirconium oxide layer in the node dielectric layer 15 may be annealed into a respective crystalline hafnium zirconium oxide layer 151 by performing a laser anneal process in which a laser beam irradiates each of the at least one amorphous hafnium zirconium oxide layer. The laser anneal process may be performed prior to, or after, formation of the second metallic electrode layer 20. According to an aspect of the present disclosure, the lateral dimensions of each of the vertically-extending portions of the contoured trenches 109 may be selected to enable irradiation of a laser beam to bottom portions of the node dielectric layer 15 that are formed at the bottom of the contoured trenches 109. In one embodiment, the lateral dimensions of the vertically-extending portions of the contoured trenches 109 may be greater than the wavelength of the laser beam, which may be in a range from 400 nm to 1,600 nm. A capacitor structure (10, 15, 20) may be formed.

Subsequently, second dielectric material layers 62 having second metal interconnect structures 82 formed therein may be formed over the capacitor structure 20. The second dielectric material layers 62 may comprise any interlayer dielectric (ILD) material known in the art. The second metal interconnect structures 82 may comprise metal line structures and metal via structures. The total number of the metal line levels within the second metal interconnect structures 82 may be in a range from 1 to 20. Metallic bonding structures 98 may be formed over the second metal interconnect structures 82.

Referring to FIG. 11C, the substrate 8 may be thinned from the backside, for example, by grinding, polishing, an anisotropic etch process, or an isotropic etch process. The backside surfaces of the through-substrate via structures 6 may be exposed upon thinning of the substrate 8. The backside surface of the substrate 8 may be further recessed, and a backside insulating layer 106 may be formed on the recessed backside surface of the substrate 8. Backside bonding structures 22 may be formed on the backside surfaces of the through-substrate via structures 6. The second embodiment structure may be diced into a plurality of semiconductor dies 1100, each of which may be a semiconductor structure including a respective set of at least one capacitor structure (10, 15, 20).

Referring collectively to FIGS. 1-11B and according to various embodiments of the present disclosure, a device structure is provided, which comprises: a first metallic electrode layer 10 overlying, or located within, a substrate 8; a node dielectric layer 15 comprising a crystalline hafnium zirconium oxide layer 151 having a material composition of Hf_{(1-α)}Zr_{α}O₂ , wherein a value of α is in a range from 0.50 to 0.90; and a second metallic electrode layer 20 over the node dielectric layer 15. The sum of the fraction of hafnium zirconium oxide in the tetragonal phase and the fraction of hafnium zirconium oxide in the orthorhombic phase for the crystalline hafnium zirconium oxide layer 151 is greater than 0.40 for the crystalline hafnium zirconium oxide layer 151. The combination of the first electrode layer, the node dielectric layer 15, and the second metallic electrode layer 20 comprises a capacitor structure (10, 15, 20).

In one embodiment, the fraction of hafnium zirconium oxide in the tetragonal phase is greater than the fraction of hafnium zirconium oxide in the orthorhombic phase. In one embodiment, the node dielectric layer 15 comprises a first high band gap dielectric layer 155 comprising a first dielectric material having a first band gap greater than 6 eV. In one embodiment, the crystalline hafnium zirconium oxide layer 151 comprises tetragonal phase portions and orthorhombic phase portions including a ferroelectric material. The high band gap dielectric layer 155 reduces ferroelectric polarization switching of the ferroelectric material by increasing a depolarization field.

In one embodiment, the node dielectric layer 15 further comprises: an additional crystalline hafnium zirconium oxide layer 151 having a material composition of Hf_{(1-β)}Zr_{β}O₂, wherein a value of β is in a range from 0.50 to 0.90; and a second high band gap dielectric layer 155 comprising a second dielectric material having a second band gap greater than 6 eV.

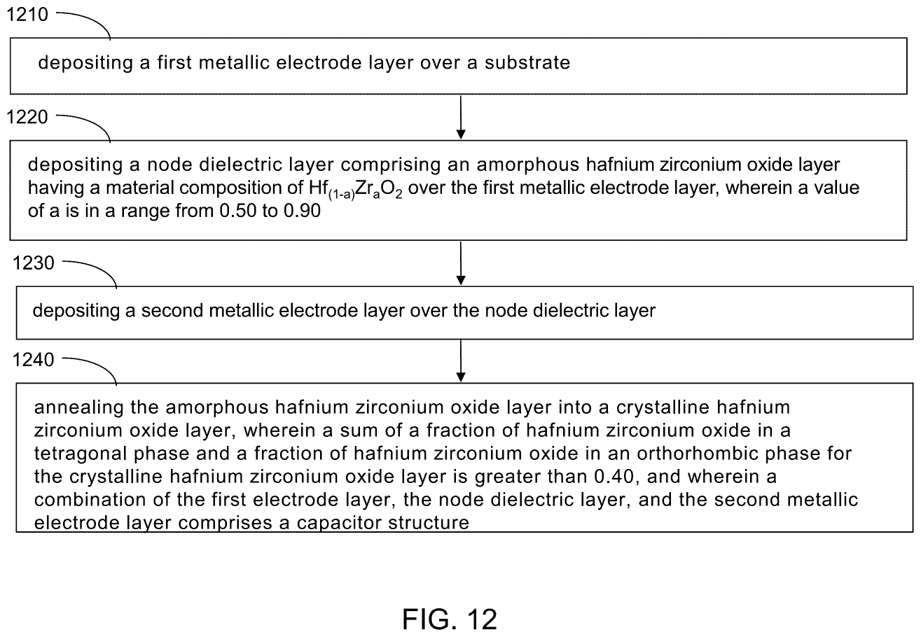

FIG. 12 is a first flowchart that illustrates the general processing steps of the methods of the present disclosure.

Referring to step 1210 and FIGS. 2A-2J, 3A-4, 8A, 9A and 9B, 10A and 10B, and 11A and 11B, a first metallic electrode layer 10 may be deposited over a substrate 8.

Referring to step 1220 and FIGS. 1, 2A-2J, 4, 8A, 9B, 10B, and 11B, a node dielectric layer 15 comprising an amorphous hafnium zirconium oxide layer having a material composition of Hf_{(1-α)}Zr_{α}O₂ may be deposited over the first metallic electrode layer 10. The value of α may be in a range from 0.50 to 0.90.

Referring to step 1230 and FIGS. 2A-2J, 4, 8A, 9B, 10B, and 11B, a second metallic electrode layer 20 may be deposited over the node dielectric layer 15.

Referring to step 1240 and FIGS. 1, 2A-2J, 4-7, 8A-8C, 9B and 9C, 10B and 10C, and 11B and 11C, the amorphous hafnium zirconium oxide layer may be annealed into a crystalline hafnium zirconium oxide layer 151. The sum of the fraction of hafnium zirconium oxide in the tetragonal phase and the fraction of hafnium zirconium oxide in the orthorhombic phase for the crystalline hafnium zirconium oxide layer 151 is greater than 0.40. A combination of the first metallic electrode layer 10, the node dielectric layer 15, and the second metallic electrode layer 20 comprises a capacitor structure (10, 15, 20).

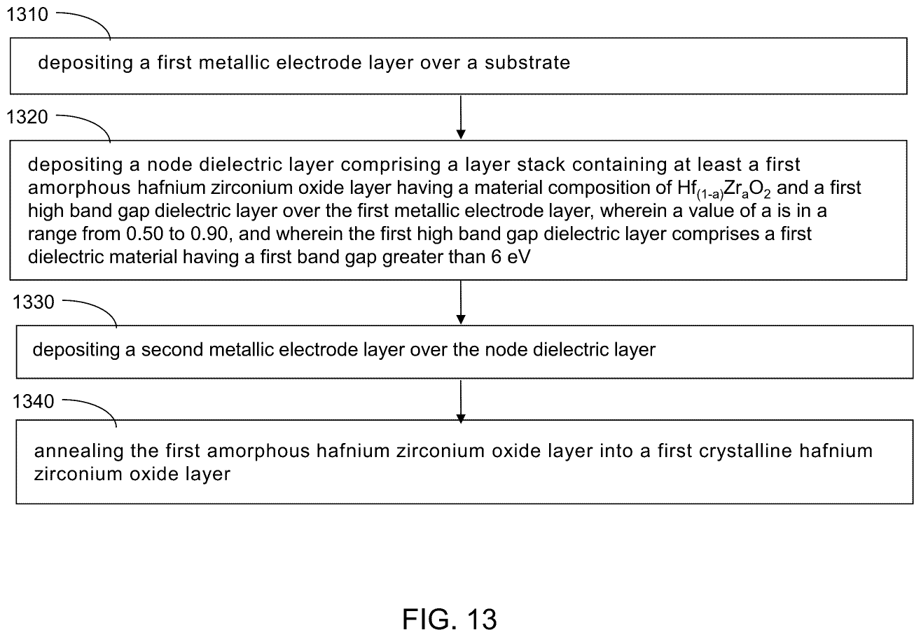

FIG. 13 is a second flowchart that illustrates the general processing steps of the methods of the present disclosure.

Referring to step 1310 and FIGS. 2A-2J, 3A-4, 8A, 9A and 9B, 10A and 10B, and 11A and 11B, a first metallic electrode layer 10 may be deposited over a substrate 8.

Referring to 1420 and FIGS. 1, 2B-2J, 4, 8A, 9B, 10B, and 11B, a node dielectric layer 15 comprising a layer stack containing at least a first amorphous hafnium zirconium oxide layer having a material composition of Hf_{(1-α)}Zr_{α}O₂ and a first high band gap dielectric layer 155 may be deposited over the first metallic electrode layer 10. The value of α is in a range from 0.50 to 0.90. The first high band gap dielectric layer 155 comprises a first dielectric material having a first band gap greater than 6 eV.

Referring to step 1330 and FIGS. 2A-2J, 4, 8A, 9B, 10B, and 11B, a second metallic electrode layer 20 may be deposited over the node dielectric layer 15.

Referring to step 1340 and FIGS. 1, 2A-2J, 4-7, 8A-8C, 9B and 9C, 10B and 10C, and 11B and 11C, the first amorphous hafnium zirconium oxide layer may be annealed into a first crystalline hafnium zirconium oxide layer.

Embodiments of the present disclosure utilizes the tetragonal phase of a crystalline hafnium zirconium oxide material in the node dielectric layer 15. The tetragonal phase of a crystalline hafnium zirconium oxide material offers a higher dielectric constant than alternative phases of hafnium zirconium oxide material, enabling construction of a metal-insulator-metal capacitor with higher capacitance per unit area. In some embodiments, leakage currents may be reduced and thermal stability of the crystalline hafnium zirconium oxide material may be enhanced by including high band gap dielectric layers 155. High band gap dielectric layers 155 may act as barriers to reduce tunneling effects. Furthermore, the stacked structure of alternating hafnium zirconium oxide layers 151 and high band gap dielectric layers 155 enhances control over formation of the crystallographic phases during an anneal process, thus improving the overall performance and reliability of the capacitor structure. This combination of materials and structural features provides various advantages for capacitor structures of the present disclosure over traditional capacitors, such as enhanced field localization, reduced phase transition risks, and enhanced temperature stability.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
depositing a first metallic electrode layer over a substrate;
depositing a node dielectric layer comprising an amorphous hafnium zirconium oxide layer having a material composition of Hf_{(1-α)}Zr_{α}O₂ over the first metallic electrode layer, wherein a value of α is in a range from 0.50 to 0.90;
depositing a second metallic electrode layer over the node dielectric layer; and
annealing the amorphous hafnium zirconium oxide layer into a crystalline hafnium zirconium oxide layer.

2. The method of claim 1, wherein a sum of a fraction of hafnium zirconium oxide in a tetragonal phase and a fraction of hafnium zirconium oxide in an orthorhombic phase for the crystalline hafnium zirconium oxide layer is greater than 0.40.

3. The method of claim 2, wherein the fraction of hafnium zirconium oxide in the tetragonal phase is greater than the fraction of hafnium zirconium oxide in the orthorhombic phase.

4. The method of claim 2, wherein the fraction of hafnium zirconium oxide in the tetragonal phase is greater than the fraction of hafnium zirconium oxide in a monoclinic phase.

5. The method of claim 1, wherein:
the sum of the fraction of hafnium zirconium oxide in the tetragonal phase and the fraction of hafnium zirconium oxide in the orthorhombic phase is greater than 0.50; and
the fraction of hafnium zirconium oxide in the tetragonal phase is greater than 0.05.

6. The method of claim 1, wherein:
the substrate comprises a semiconductor substrate;
the method comprises forming a vertically-extending trench in an upper portion of the semiconductor substrate; and
each of the first metallic electrode layer, the node dielectric layer, and the second metallic electrode layer comprises a respective vertically-extending portion that is formed within a volume of the vertically-extending trench.

7. The method of claim 1, wherein:
the method comprises forming first dielectric material layers with first metal interconnect structures formed therein over the substrate;
the first metallic electrode layer and the node dielectric layer are deposited over a top surface of the first dielectric material layers; and
the amorphous hafnium zirconium oxide layer is annealed into the crystalline hafnium zirconium oxide layer by performing a laser anneal process in which a laser beam irradiates the amorphous hafnium zirconium oxide layer.

8. The method of claim 1, further comprising:
forming first dielectric material layers with first metal interconnect structures formed therein over the substrate;
forming a contoured trench in the first dielectric material layers, wherein:
the contoured trench comprises a horizontally-extending portion and a vertically-extending portion that is adjoined to the horizontally-extending portion;
a sidewall of one of the first metal interconnect structures is exposed around the vertically-extending portion; and
the first metallic electrode layer is deposited directly on the sidewall of said one of the first metal interconnect structures.

9. The method of claim 1, further comprising:
forming first dielectric material layers with first metal interconnect structures formed therein over the substrate;
forming a contoured trench in the first dielectric material layers, wherein:
the contoured trench comprises a horizontally-extending portion and a vertically-extending portion that is adjoined to the horizontally-extending portion;
a top surface of one of the first metal interconnect structures is exposed at a bottom of the vertically-extending portion; and
the first metallic electrode layer is deposited directly on the top surface of said one of the first metal interconnect structures.

10. The method of claim 1, wherein:
the substrate comprises a semiconductor substrate;
the method comprises forming through-substrate via structures in an upper portion of the semiconductor substrate, forming first dielectric material layers with first metal interconnect structures formed therein over the semiconductor substrate, and forming a contoured trench in the first dielectric material layers;
the contoured trench comprises a horizontally-extending portion and a vertically-extending portion that is adjoined to the horizontally-extending portion;
a top surface and a sidewall of one of the through-substrate via structures are exposed at a bottom of the vertically-extending portion upon formation of the contoured trench; and
the first metallic electrode layer is deposited directly on the sidewall of said one of the through-substrate via structures.

11. A method of forming a device structure, comprising:
depositing a first metallic electrode layer over a substrate;
depositing a node dielectric layer comprising a layer stack containing at least a first amorphous hafnium zirconium oxide layer having a material composition of Hf_{(1-α)}Zr_{α}O₂ and a first high band gap dielectric layer over the first metallic electrode layer, wherein a value of α is in a range from 0.50 to 0.90, and wherein the first high band gap dielectric layer comprises a first dielectric material having a first band gap greater than 6 eV;
depositing a second metallic electrode layer over the node dielectric layer; and
annealing the first amorphous hafnium zirconium oxide layer into a first crystalline hafnium zirconium oxide layer.

12. The method of claim 11, wherein:
the first crystalline hafnium zirconium oxide layer comprises tetragonal phase portions and orthorhombic phase portions including a ferroelectric material; and
the first high band gap dielectric layer reduces ferroelectric polarization switching of the ferroelectric material by increasing a depolarization field.

13. The method of claim 11, wherein the layer stack contains a second amorphous hafnium zirconium oxide layer that is formed on first high band gap dielectric layer having a material composition of Hf_{(1-β)}Zr_{β}O₂ over the first metallic electrode layer, wherein a value of β is in a range from 0.50 to 0.90.

14. The method of claim 11, wherein the layer stack contains a second high band gap dielectric layer that is formed on the first amorphous hafnium zirconium oxide layer and comprises a second dielectric material having a second band gap greater than 6 eV.

15. The method of claim 11, wherein the layer stack comprises:
a second amorphous hafnium zirconium oxide layer which has a material composition of Hf_{(1-β)}Zr_{β}O₂, and is formed over the first high band gap dielectric layer, wherein a value of α is in a range from 0.50 to 0.90; and
a second high band gap dielectric layer that is formed over the second amorphous hafnium zirconium oxide layer metallic electrode layer, wherein the second high band gap dielectric layer comprises a second dielectric material having a second band gap greater than 6 eV.

16. A device structure comprising:
a first metallic electrode layer overlying, or located within, a substrate;
a node dielectric layer comprising a crystalline hafnium zirconium oxide layer having a material composition of Hf_{(1-β)}Zr_{β}O₂ wherein a value of α is in a range from 0.50 to 0.90; and
a second metallic electrode layer over the node dielectric layer, wherein a fraction of hafnium zirconium oxide in a tetragonal phase is greater than a fraction of hafnium zirconium oxide in an orthorhombic phase for the crystalline hafnium zirconium oxide layer.

17. The device structure of claim 16, wherein the fraction of hafnium zirconium oxide in the tetragonal phase is greater than the fraction of hafnium zirconium oxide in the orthorhombic phase.

18. The device structure of claim 16, wherein the node dielectric layer comprises a first high band gap dielectric layer comprising a first dielectric material having a first band gap greater than 6 eV.

19. The device structure of claim 18, wherein:
the crystalline hafnium zirconium oxide layer comprises tetragonal phase portions and orthorhombic phase portions including a ferroelectric material; and
a high band gap dielectric layer reduces ferroelectric polarization switching of the ferroelectric material by increasing a depolarization field.

20. The device structure of claim 16, wherein the node dielectric layer further comprises:
an additional crystalline hafnium zirconium oxide layer having a material composition of Hf_{(1-β)}Zr_{β}O₂, wherein a value of β is in a range from 0.50 to 0.90; and
a second high band gap dielectric layer comprising a second dielectric material having a second band gap greater than 6 eV.
